(19) United States
(12) Patent Application Publication
(10) Pub. No.: US 2025/0384901 A1
(43) Pub. Date: Dec. 18, 2025

(54) SEMICONDUCTOR DEVICE, METHOD OF MANUFACTURING THEREOF AND MEMORY SYSTEM

(71) Applicant: Yangtze Memory Technologies Co., Ltd., Wuhan (CN)

(72) Inventors: Zongliang HUO, Wuhan (CN); Zengpeng Zhang, Wuhan (CN); Wenbo Zhang, Wuhan (CN); Tingting Zhao, Wuhan (CN); Sizhe Li, Wuhan (CN); Jing Gao, Wuhan (CN)

(21) Appl. No.: 19/238,134

(22) Filed: Jun. 13, 2025

Related U.S. Application Data
(60) Provisional application No. 63/661,018, filed on Jun. 17, 2024.

(30) Foreign Application Priority Data
Jun. 28, 2024 (CN) 202410857709.7

(51) Int. Cl. G11C 5/06; H10B 43/10; H10B 43/27; H10B 43/40

(52) U.S. Cl. CPC G11C 5/06; H10B 43/10; H10B 43/27; H10B 43/40

(57) ABSTRACT

According to one aspect of the present disclosure, a semiconductor device is provided. The semiconductor device may include a stacked structure comprising gate layers stacked along a first direction. The semiconductor device may include a stair unit structure located in the stacked structure and comprising a plurality of wrapping-around stair steps. The semiconductor device may include a contact structure penetrating through the stair step along the first direction and connected with the gate layer.

### CROSS-REFERENCE TO RELATED APPLICATIONS

This application claims the benefit of priorities to Chinese Application No. 202410857709.7, filed on Jun. 28, 2024, and U.S. Provisional Application No. 63/661,018, filed on Jun. 17, 2024, both of which are hereby incorporated by reference in their entireties.

### TECHNICAL FIELD

The present disclosure relates to the field of semiconductor design and manufacturing, and more particularly, to a semiconductor device, a method of manufacturing a semiconductor device, and a memory system.

### BACKGROUND

With the rise and development in the fields of artificial intelligence (AI), big data, Internet of Things, mobile communication, mobile devices, and cloud storage, requirements for the storage density of a semiconductor device such as a three-dimensional (3D) memory are also increasing. However, due to limiting factors such as a process, a device, and a material, it has become difficult to improve the storage density of the semiconductor device.

In addition, as the number of stacked layers increases and the storage density per unit area increases in a semiconductor device such as a three-dimensional memory, the process steps in the manufacturing process of the semiconductor device become complex and lengthy, and the manufacturing cost of the semiconductor device is also gradually increased.

Therefore, how to simplify the manufacturing process of the semiconductor device, reduce the manufacturing cost of the semiconductor device, and improve the storage density of the semiconductor device is an urgent problem to be solved currently.

### SUMMARY

According to one aspect of the present disclosure, a semiconductor device is provided. The semiconductor device may include a stacked structure including gate layers stacked along a first direction. The semiconductor device may include a stair unit structure located in the stacked structure and including a plurality of wrapping-around stair steps. The semiconductor device may include a contact structure penetrating through the stair step along the first direction and connected with the gate layer.

In some implementations, the stacked structure may include two surfaces opposite to each other in the first direction. In some implementations, the stair unit structure may include a plurality of stair unit structures. In some implementations, distances between the stair steps of the plurality of the stair unit structures and one of the two surfaces in the first direction may be different.

In some implementations, in a direction intersecting with the first direction, a plurality of stair steps of a same stair unit structure may have different sizes.

In some implementations, a shape of a cross section of the stair unit structure in a plane intersecting with the first direction may include at least one of a circle, an ellipse, a polygon, and a sector.

In some implementations, a shape of a cross section of the stair step in a plane intersecting with the first direction may include an annular shape. In some implementations, the annular shape may include at least one of a circular ring, an elliptical ring, a polygonal ring, and a sector ring.

In some implementations, the stacked structure may include a first side and a second side opposite to each other in the first direction. In some implementations, lengths of a plurality of stair steps of at least one stair unit structure may increase from the first side to the second side. In some implementations, the lengths may be sizes of the stair steps in a direction intersecting with the first direction.

In some implementations, the stair unit structure may include a plurality of stair unit structures. In some implementations, the plurality of stair unit structures may have a different numbers of stair steps.

In some implementations, the stair unit structure may include a plurality of sub-regions. In some implementations, each sub-region of the plurality of sub-regions may include a plurality of stair steps. In some implementations, the stacked structure may include two surfaces opposite to each other in the first direction, and distances between the plurality of sub-regions and one of the two surfaces in the first direction may be different.

In some implementations, the plurality of sub-regions may have different numbers of stair steps.

In some implementations, distances between the stair steps of the plurality of sub-regions and one of the two surfaces in the first direction may be different.

In some implementations, the stacked structure may include a plurality of sub-stacked structures stacked along the first direction. In some implementations, the contact structure may be connected to the gate layers of the plurality of sub-stacked structures.

In some implementations, a portion of the contact structure in the sub-stacked structure may include a first contact portion extending to a surface of the gate layer along the first direction and connected with the surface. In some implementations, a portion of the contact structure in the sub-stacked structure may include a second contact portion connected with the first contact portion and penetrating through the stair step in the first direction.

In some implementations, a portion of the first contact portion extending to the surface may extend in a direction intersecting with the first direction.

In some implementations, the stair step may include a cover dielectric layer covering the surface. In some implementations, a portion of the first contact portion extending to the surface may be located in the cover dielectric layer.

In some implementations, the semiconductor device may include a peripheral circuit structure. In some implementations, the first contact portion or the second contact portion of the contact structure may connect the gate layer with the peripheral circuit structure.

In some implementations, the peripheral circuit structure may include a first peripheral circuit disposed on a first side of the stacked structure. In some implementations, the peripheral circuit structure may include a second peripheral circuit disposed on a second side of the stacked structure. In some implementations, the first side and the second side may be opposite to each other along the first direction. In some implementations, the first contact portion may be closer to the first side than the second contact portion. In some implementations, the first contact portion may connect the gate layer with the first peripheral circuit, or the second contact portion may connect the gate layer with the second peripheral circuit.

In some implementations, the contact structure may include a conductive core layer. In some implementations, the contact structure may include an adhesive layer surrounding the conductive core layer. In some implementations, the contact structure may include a blocking layer surrounding the adhesive layer and including first and second sub-layers spaced apart from each other in a direction intersecting with the first direction.

In some implementations, the first and second sub-layers may include different insulating dielectric materials.

In some implementations, the stacked structure may include a first sub-stacked structure and a second sub-stacked structure disposed on a side of the first sub-stacked structure along the first direction. In some implementations, the contact structure may include a first sub-portion, a second sub-portion, and a third sub-portion connected to each other along the first direction. In some implementations, the first sub-portion and a portion of the second sub-portion may be located in the first sub-stacked structure, and the other portion of the second sub-portion and the third sub-portion may be located in the second sub-stacked structure.

In some implementations, the semiconductor device may include a peripheral circuit structure disposed on a first side of the stacked structure along the first direction. In some implementations, the second sub-portion may be closer to the peripheral circuit structure than the first sub-portion, a first end of the first sub-portion may be connected with a second end of the second sub-portion, and in a direction intersecting with the first direction, a size of the first end may be greater than a size of the second end. In some implementations, the third sub-portion may be closer to the peripheral circuit structure than the second sub-portion, a third end of the second sub-portion may be connected with a fourth end of the third sub-portion, and in a direction intersecting with the first direction, a size of the third end may be greater than a size of the fourth end.

In some implementations, the semiconductor device may include a peripheral circuit structure disposed on a first side of the stacked structure along the first direction. In some implementations, at least one of the first sub-portion, the second sub-portion, and the third sub-portion may include an end and the other end opposite to each other along the first direction, and the end may be closer to the peripheral circuit structure than the other end. In some implementations, in a direction intersecting with the first direction, a size of the end may be larger than a size of the other end.

In some implementations, the stacked structure may include a first sub-stacked structure and a second sub-stacked structure disposed on a side of the first sub-stacked structure along the first direction. In some implementations, the semiconductor device may further include a first semiconductor layer located between the first sub-stacked structure and the second sub-stacked structure along the first direction and extending along a direction intersecting with the first direction.

In some implementations, the semiconductor device may include a channel structure. In some implementations, the semiconductor device may include a channel layer extending along the first direction and connected with the first semiconductor layer. In some implementations, the semiconductor device may include a functional layer surrounding the channel layer and including a first functional layer and a second functional layer. In some implementations, the first functional layer may extend in the first sub-stacked structure along the first direction, and the second functional layer may extend in the second sub-stacked structure along the first direction.

In some implementations, a doping type of the channel layer and the first semiconductor layer may be the same.

In some implementations, a doping concentration of a conductive impurity of the first semiconductor layer may be greater than a doping concentration of a conductive impurity of the channel layer.

In some implementations, the stacked structure may include a plurality of sub-stacked structures stacked along the first direction. In some implementations, the semiconductor device may include a second semiconductor layer located on a side of the sub-stacked structure along the first direction and extending along a direction intersecting with the first direction. In some implementations, the second semiconductor layers of the plurality of sub-stacked structures may be connected to each other.

In some implementations, the semiconductor device may include a peripheral circuit structure disposed on a first side of the stacked structure along the first direction. In some implementations, the second semiconductor layer may be located on a side of the sub-stacked structure away from the peripheral circuit structure along the first direction.

In some implementations, the semiconductor device may include a channel structure. In some implementations, the channel structure may include sub-channel structures located in different sub-stacked structures. In some implementations, the sub-channel structure may include a sub-channel layer and a sub-functional layer surrounding the sub-channel layer. In some implementations, the sub-channel layer may extend into the second semiconductor layer along the first direction.

In some implementations, a doping type of the sub-channel layer and the second semiconductor layer may be the same.

In some implementations, a doping concentration of a conductive impurity of the second semiconductor layer may be greater than a doping concentration of a conductive impurity of the sub-channel layer.

In some implementations, the stacked structure may include a plurality of sub-stacked structures stacked along the first direction. In some implementations, the plurality of sub-stacked structures may have different numbers of gate layers.

According to another aspect of the present disclosure, a method of manufacturing a semiconductor device may be included. The method may include alternately stacking insulating dielectric layers and gate sacrificial layers along a first direction to form a stacked structure. The method may include forming an initial stair unit structure in the stacked structure. The initial stair unit structure may include a plurality of wrapping-around initial stair steps. The method may include forming a contact hole penetrating the initial stair step along the first direction and connected with the gate sacrificial layer. The method may include removing the gate sacrificial layer and forming a contact structure in the contact hole.

In some implementations, the method may include, after the initial stair step is formed, forming a cover sacrificial layer on a portion of the gate sacrificial layer on a surface of the initial stair step. In some implementations, the method may include, after removing the gate sacrificial layer to form a gate layer, removing a portion of the cover sacrificial layer via the contact hole. In some implementations, the contact structure may be connected with a surface of the gate layer exposed after removing the portion of the cover sacrificial layer.

In some implementations, forming the initial stair unit structure in the stacked structure may include forming a plurality of wrapping-around initial stair steps. In some implementations, forming the initial stair unit structure in the stacked structure may include removing a portion of the initial stair step, so that the same initial stair step is formed as stair steps of a plurality of initial sub-regions adjacent to each other. In some implementations, the stacked structure may include two surfaces opposite to each other in the first direction. In some implementations, distances between the stair steps of the plurality of initial sub-regions and one of the two surfaces in the first direction are different.

In some implementations, forming the stacked structure may include alternately stacking a first insulating dielectric layer and a first gate sacrificial layer to form a first sub-stacked structure. In some implementations, forming the stacked structure may include forming a first semiconductor layer on a side of the first sub-stacked structure along the first direction. In some implementations, forming the stacked structure may include alternately stacking a second insulating dielectric layer and a second gate sacrificial layer on a side of a first semiconductor layer along the first direction to form a second sub-stacked structure. In some implementations, the first sub-stacked structure and the second sub-stacked structure may constitute the stacked structure.

In some implementations, the method may include forming a channel structure. In some implementations, the forming the channel structure may include forming a channel hole extending in the first sub-stacked structure and the second sub-stacked structure along the first direction. In some implementations, the channel hole may expose a portion of the first semiconductor layer. In some implementations, the forming the channel structure may include forming an initial functional layer in the channel hole. In some implementations, the forming the channel structure may include removing a portion of the initial functional layer on the exposed portion of the first semiconductor layer to form a first functional layer and a second functional layer. In some implementations, the first functional layer may extend in the first sub-stacked structure along the first direction, and the second functional layer may extend in the second sub-stacked structure along the first direction. In some implementations, the forming the channel structure may include forming a channel layer on surfaces of the first functional layer, the first semiconductor layer, and the second functional layer.

According to a further aspect of the present disclosure, a memory system may include at least one semiconductor device. The at least one semiconductor device may include a stacked structure including gate layers stacked along a first direction. The at least one semiconductor device may include a stair unit structure located in the stacked structure and including a plurality of wrapping-around stair steps. The at least one semiconductor device may include a contact structure penetrating through the stair step along the first direction and connected with the gate layer. The memory system may include a controller coupled to the semiconductor device and configured to control the semiconductor device to store data.

### BRIEF DESCRIPTION OF DRAWINGS

Other features, objects and benefits of the present disclosure will become more apparent upon reading the detailed description of non-limiting implementations made below with reference to the drawings.

FIG. 1 is a schematic partial top view of a semiconductor device according to an implementation of the present disclosure;

FIG. 2 is a schematic partial top view of a semiconductor device according to another implementation of the present disclosure;

FIG. 3 is a schematic partial top view of a semiconductor device according to yet another implementation of the present disclosure;

FIG. 4 is a schematic partial top view of a semiconductor device according to yet another implementation of the present disclosure;

FIG. 5 is a schematic partial stereoscopic view of a semiconductor device according to an implementation of the present disclosure;

FIG. 6 is a schematic cross-sectional view of the semiconductor device shown in FIG. 2 taken along line A-A′;

FIG. 7 is a schematic partial cross-sectional view of a semiconductor device according to an implementation of the present disclosure;

FIG. 8 is a schematic partial cross-sectional view of a semiconductor device according to another implementation of the present disclosure;

FIG. 9 is a schematic partial cross-sectional view of a semiconductor device according to yet another implementation of the present disclosure;

FIG. 10 is a schematic partial cross-sectional view of a semiconductor device according to an implementation of the present disclosure;

FIG. 11 is a schematic partial cross-sectional view of a semiconductor device according to an implementation of the present disclosure;

FIG. 12 is a schematic cross-sectional view of a contact structure according to an implementation of the present disclosure;

FIG. 13 is a flowchart of a method of manufacturing a semiconductor device according to an implementation of the present disclosure;

FIGS. 14-32 are schematic process diagrams of a method of manufacturing a semiconductor device according to an implementation of the present disclosure; and

FIG. 33 is a schematic structural diagram of a memory system according to an implementation of the present disclosure.

### DETAILED DESCRIPTION

The present disclosure will be described in detail below with reference to the accompanying drawings, and the exemplary implementations mentioned herein are only for explaining the present disclosure, and are not intended to limit the scope of the present disclosure. Throughout the description, like reference numbers refer to like elements.

In the drawings, the thickness, size, and shape of the components have been slightly adjusted for ease of illustration. The drawings are merely examples and are not drawn to scale. As used herein, the terms “substantially,” “about,” and the like are used to represent approximations, not to represent degrees, and are intended to illustrate inherent deviations in measured values or calculated values as to be recognized by those of ordinary skill in the art.

It should also be understood that the expression “and/or” comprises any and all combinations of one or more of the associated listed items. Expressions, such as “comprise/comprising”, “include/including”, “have”, “having”, and/or “has”, and the like, are open and not closed in this disclosure, which indicate the presence of stated features, elements, and/or components, but do not preclude the presence or addition of one or more other features, elements, components, and/or combinations thereof. Furthermore, when expressions such as “at least one of” appear before the list of listed features, it modifies all of listed features rather than just modifying an individual element in the list. When describing implementations of the present disclosure, the usage of “may” is to indicate “one or more implementations of the present disclosure”. Also, the term “exemplary” is intended to refer to an example or illustration by example.

In addition, when expressions such as “connecting”, “covering”, and/or “formed on/above/over” are used in the present disclosure, it may represent a direct or indirect contact between the respective components, unless expressly defined otherwise or it can be inferred from the context. In addition, “connecting” may also represent an electrical connection, such as a circuit-on connection state in an operating state of a semiconductor device.

Unless otherwise defined, all wording (including technical terms and scientific terms) as used herein have the same meaning as those generally understood by those of ordinary skill in the art to which the present disclosure belongs. Furthermore, unless explicitly stated in the present disclosure, words defined in commonly used dictionaries should be interpreted as having a meaning that is consistent with their meaning in the context of the related art, and should not be interpreted in an idealized or overly formal sense.

It should be noted that, in the case of no conflict, implementations of the present disclosure and the features in the implementations of the present disclosure may be combined with each other. In addition, unless expressly defined or contradicted with context, the operations involved in the methods described herein are not necessarily limited to the recited order, but may be performed in any order or in parallel. The present disclosure will be described below in detail with reference to the accompanying drawings and in conjunction with the implementations.

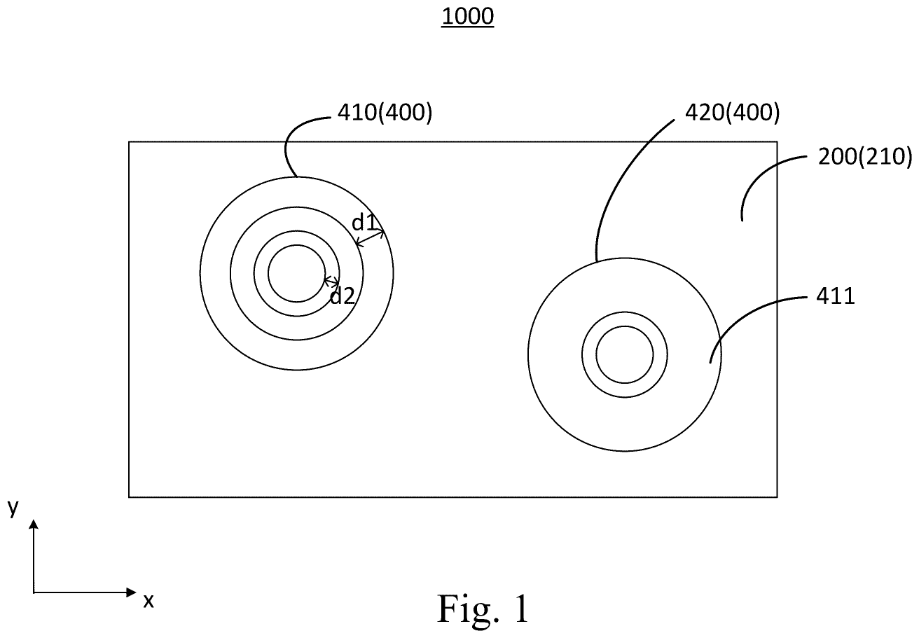

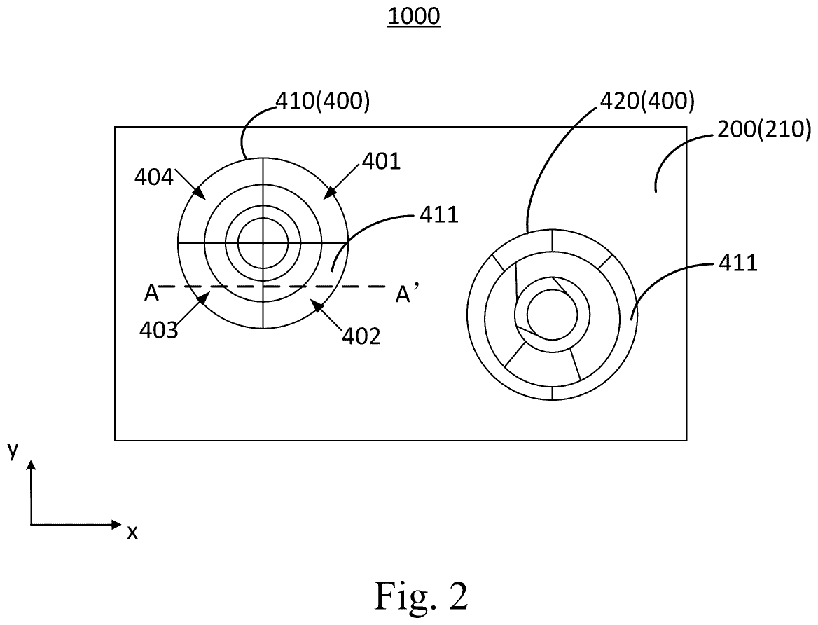

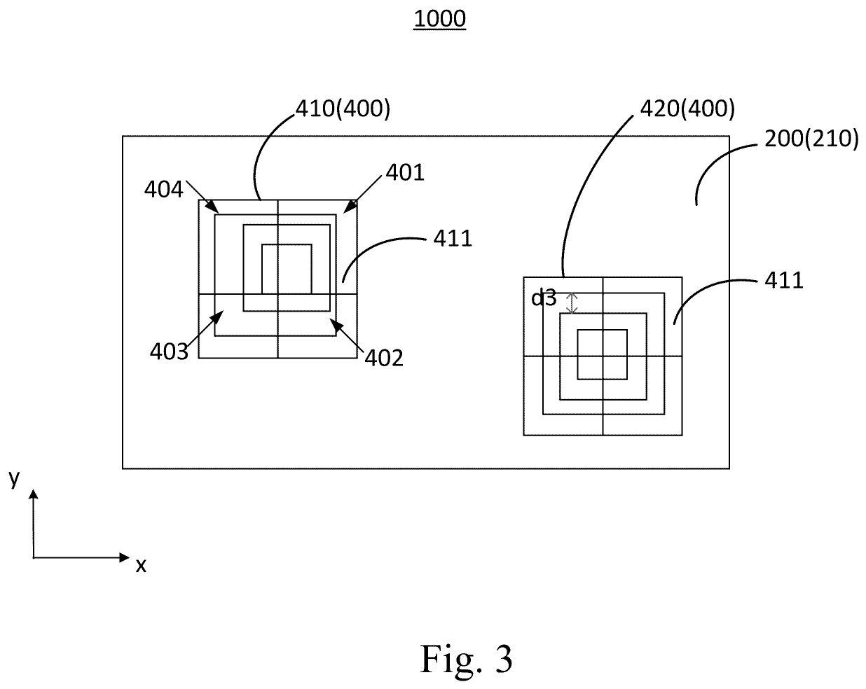

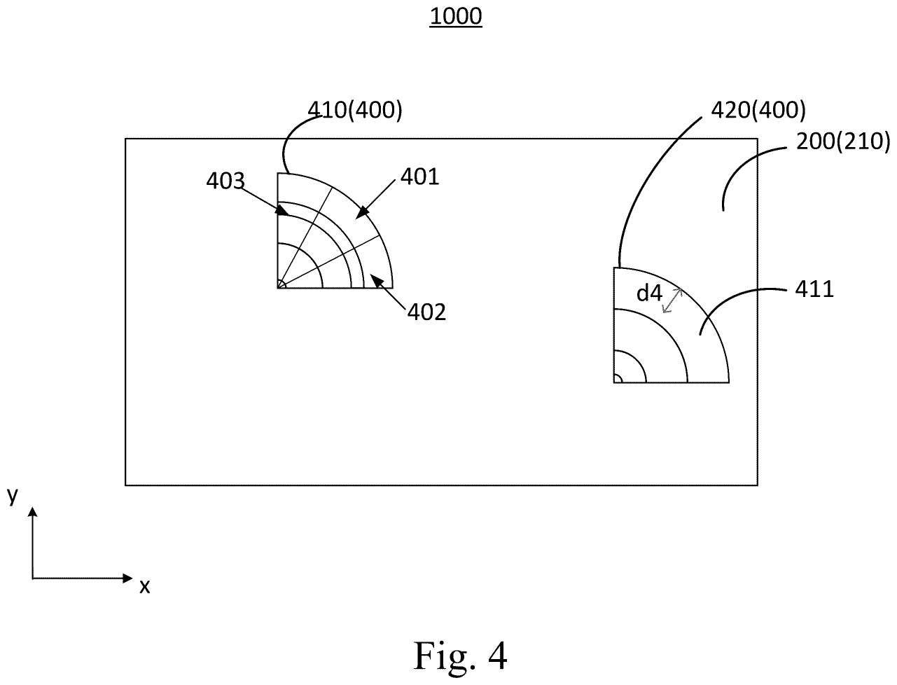

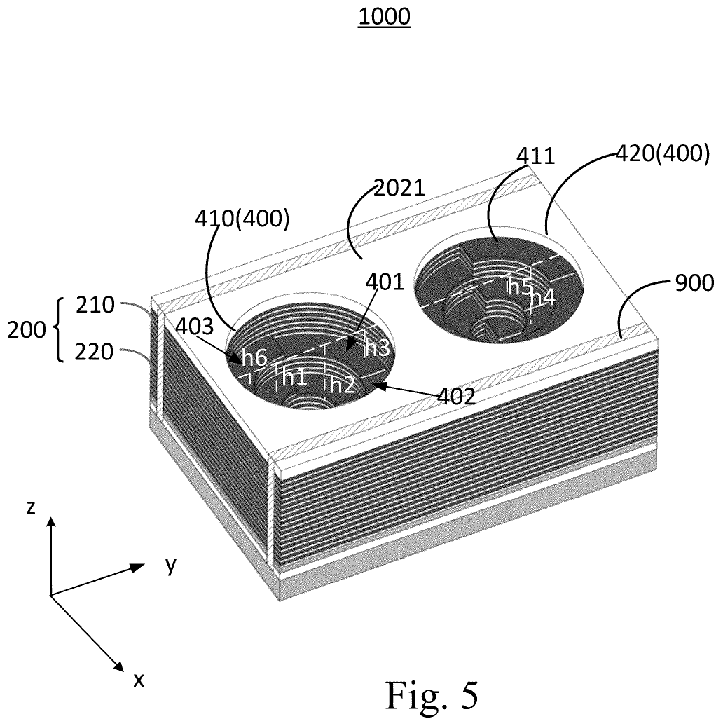

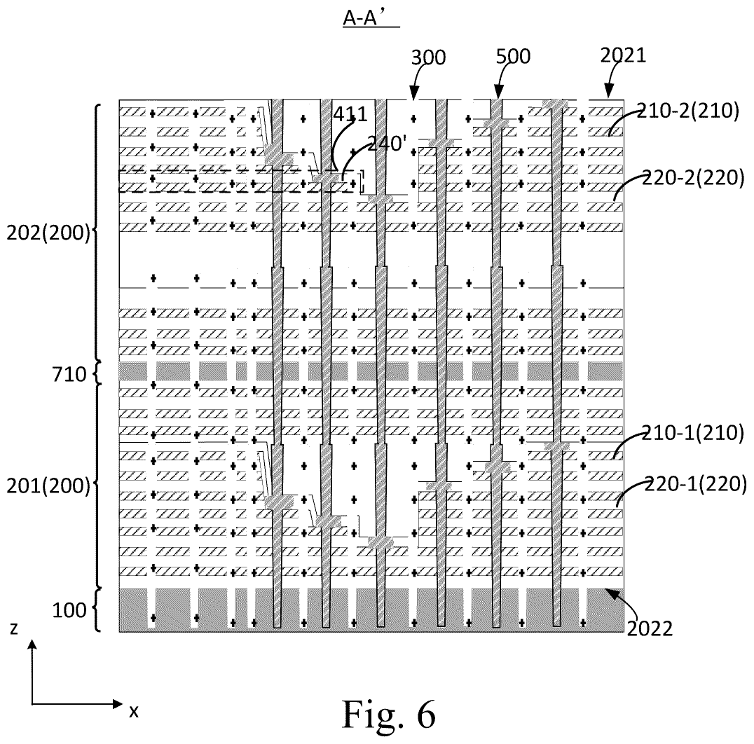

FIG. 1 is a schematic partial top view of a semiconductor device 1000 according to an implementation of the present disclosure. FIG. 2 is a schematic partial top view of a semiconductor device 1000 according to another implementation of the present disclosure. FIG. 3 is a schematic partial top view of a semiconductor device 1000 according to yet another implementation of the present disclosure. FIG. 4 is a schematic partial top view of a semiconductor device 1000 according to yet another implementation of the present disclosure. FIG. 5 is a schematic partial stereoscopic view of a semiconductor device 1000 according to an implementation of the present disclosure. FIG. 6 is a schematic cross-sectional view of the semiconductor device shown in FIG. 2 taken along line A-A′.

As shown in FIGS. 1-6, the semiconductor device 1000 includes a stacked structure 200, a stair unit structure 400, and a contact structure 500. The stacked structure 200 may include a gate layer 210 stacked along a first direction (z-direction). The stair unit structure 400 is located in the stacked structure 200 and includes a plurality of wrapping-around stair steps 411. The contact structure 500 penetrates through the stair steps 411 along the z-direction and is connected with the gate layer 210.

According to the semiconductor device provided by at least one implementation of the present disclosure, the stair unit structure of the semiconductor device is located in the stacked structure and includes a plurality of wrapping-around stair steps. By the wrapping-around stair steps, the size of the area where the stair steps are located can be reduced while the contact structure and the gate layer are effectively connected, thereby improving the storage density of the semiconductor device.

In an example, as shown in FIG. 6, the stacked structure 200 may include gate layers 210 and insulating dielectric layers 220 stacked alternately along the z-direction. In an example, the gate layer 210 may include a conductive material, such as at least one of tungsten (W), cobalt (Co), copper (Cu), aluminum (Al), doped crystalline silicon, or silicide. The insulating dielectric layer 220 is used as the insulating stacked layer of the stacked structure 200, and may include an insulating dielectric material layer. For example, the insulating dielectric layer 220 may include an insulating dielectric material layer such as silicon oxide. In addition, the number of layers of the stacked structure 200 is not limited to the number of layers shown in the figures, and may be further set as required, for example, 32 layers, 64 layers, 128 layers, etc., which is not limited in the present disclosure.

In some implementations of the present disclosure, the stacked structure 200 may be disposed on a side of a substrate 100 along the z-direction. The substrate 100 may include a layer of a semiconductor material, where the semiconductor material may include, but is not limited to, an elemental semiconductor material (e.g., silicon, germanium), a III-V compound semiconductor material, a II-VI compound semiconductor material, an organic semiconductor material, or other semiconductor materials known in the art. For example, the substrate 100 may include a silicon substrate. In addition, the substrate 100 may be a composite structure.

In addition, referring to FIGS. 5 and 6, the stacked structure 200 may further include a stack cover layer 2021, which may be located at a highest stacked layer of the stacked structure 200. For example, the stack cover layer 2021 may be a layer of the stacked structure 200 that is farthest from the substrate 100 along the z-direction. The stack cover layer 2021 may include, but is not limited to, an insulating dielectric material layer such as a silicon oxide layer.

In other words, the stacked structure 200 may include two surfaces opposite to each other in the z-direction, such as a surface of the stack cover layer 2021 and a surface of the stack isolation layer 2022, where both the stack cover layer 2021 and the stack isolation layer 2022 may include, but are not limited to, an insulating dielectric material layer such as a silicon oxide layer. The stack cover layer 2021 may be located at a highest stacked layer of the stacked structure 200, and the stack isolation layer 2022 may be located at a lowest stacked layer of the stacked structures 200. In an example, the stack isolation layer 2022 may be located on a surface of the substrate 100.

In addition, as memory capacity requirements for a semiconductor device such as a three-dimensional memory continue to increase, the above stacked layers are gradually increased. The stacked structure 200 may include a plurality of sub-stacked structures formed using techniques such as double-stack technology or multi-stack technology. The plurality of sub-stacked structures may be sequentially stacked in a stacking direction (e.g., a z-direction) to form a stacked structure 200, where the sub-stacked structure may include insulating dielectric layers and gate layers stacked on top of each other. The number of layers of the plurality of sub-stacked structures may be the same or different. The content described in the following may be applicable to a single stacked structure, or may be completely or partially applicable to a stacked structure formed by a plurality of sub-stacked structures, and therefore, related or similar contents thereof are not repeated.

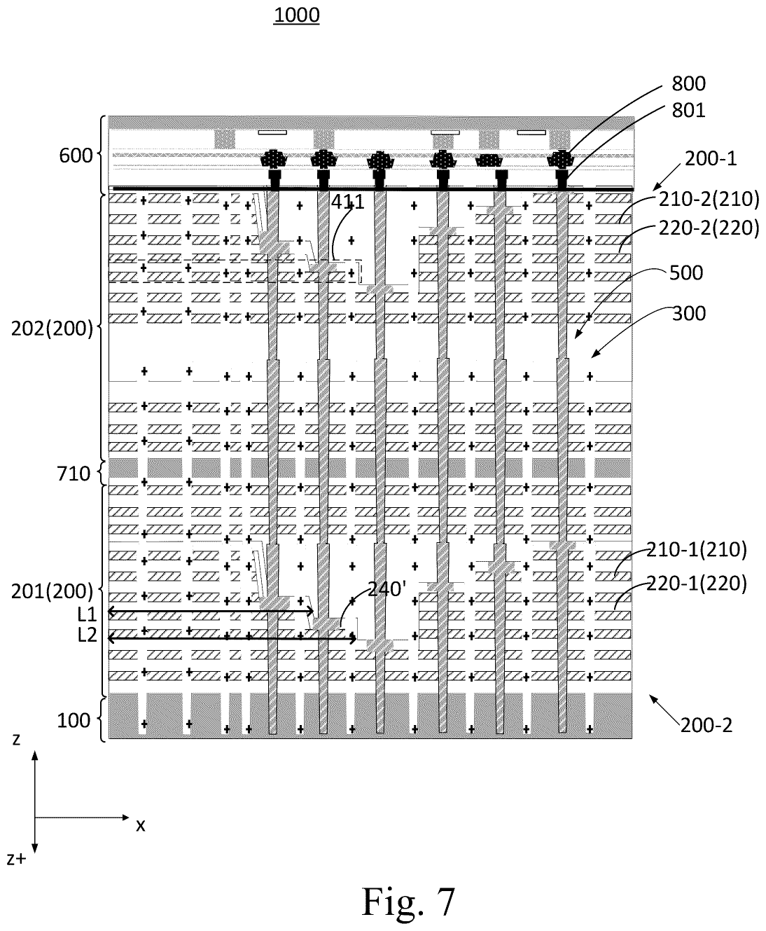

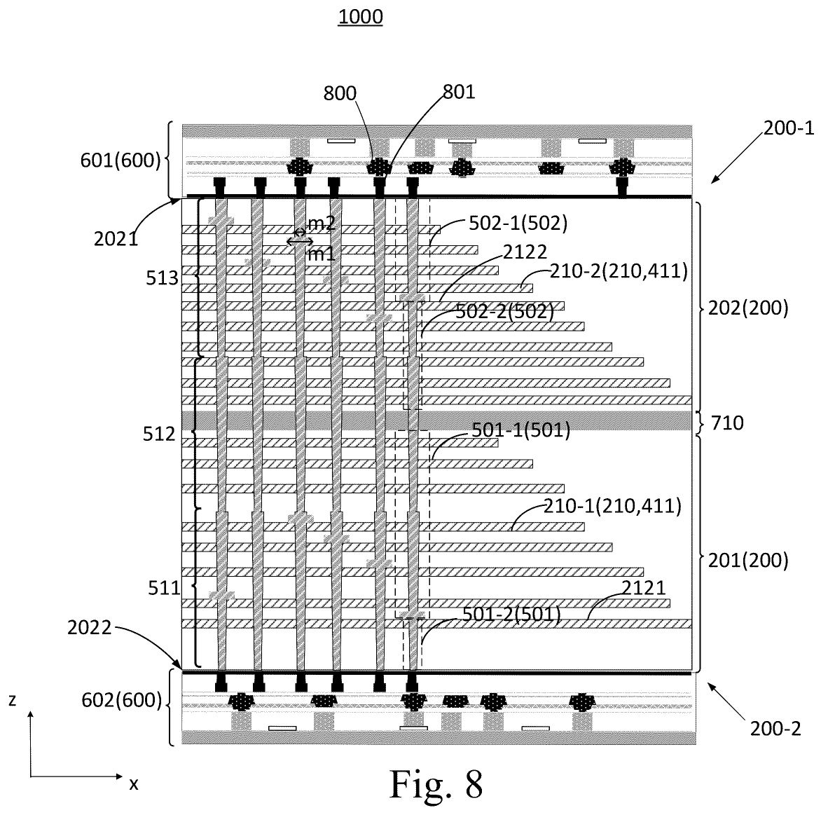

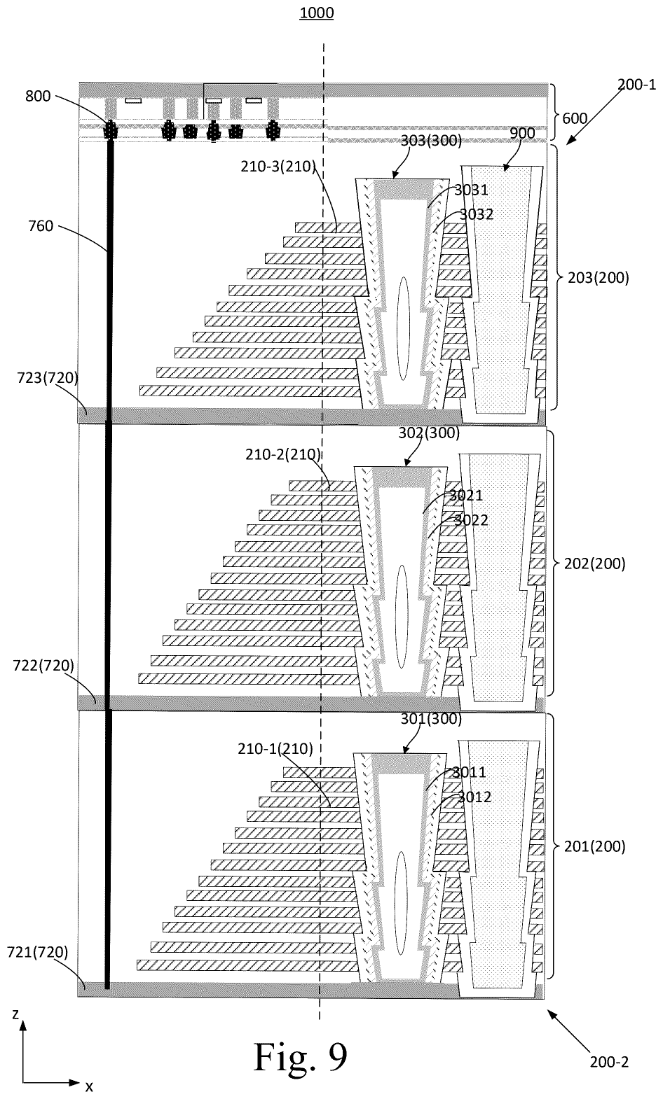

FIG. 7 is a schematic partial cross-sectional view of a semiconductor device 1000 according to an implementation of the present disclosure. FIG. 8 is a schematic partial cross-sectional view of a semiconductor device 1000 according to another implementation of the present disclosure. FIG. 9 is a schematic partial cross-sectional view of a semiconductor device 1000 according to yet another implementation of the present disclosure.

As shown in FIG. 7 and FIG. 8, as an example, the stacked structure 200 may include a plurality of sub-stacked structures stacked along the z-direction, for example, the first sub-stacked structure 201 and the second sub-stacked structure 202 located on a side of the first sub-stacked structure 201 along the z-direction. As shown in FIG. 9, as another example, the stacked structure 200 may include a plurality of sub-stacked structures stacked along the z-direction, for example, the first sub-stacked structure 201 and the remaining sub-stacked structures located on a side of the first sub-stacked structure 201 along the z-direction, for example, the second sub-stacked structure 202, the third sub-stacked structure 203, and the like.

In an example, the first sub-stacked structure 201 may include a plurality of first gate layers 210-1 stacked along the z-direction; the second sub-stacked structure 202 may include a plurality of second gate layers 210-2 stacked along the z-direction; and the third sub-stacked structure 203 may include a plurality of third gate layers 210-3 stacked in the z-direction.

Additionally, the gate layer may extend in the sub-stacked structure in a direction (e.g., x-direction) intersecting with the z-direction. For example, the first gate layer 210-1 may extend in the first sub-stacked structure 201 in a direction intersecting with the z-direction; the second gate layer 210-2 may extend in the second sub-stacked structure 202 in a direction intersecting with the z-direction; and the third gate layer 210-3 may extend in the third sub-stacked structure 203 in a direction intersecting with the z-direction, and so on.

The gate layer may include a conductive material, such as any or a combination of tungsten (W), cobalt (Co), copper (Cu), aluminum (Al), doped crystalline silicon, or silicide. In addition, the gate layers in different sub-stacked structures may include conductive material layers of the same material, or may include conductive material layers of different materials, which is not limited in the present disclosure. In an example, the number of gate layers included in different sub-stacked structures may be the same or different. In addition, the number of gate layers included in different sub-stacked structures is not limited to the number shown in the figures, and may be further set as required.

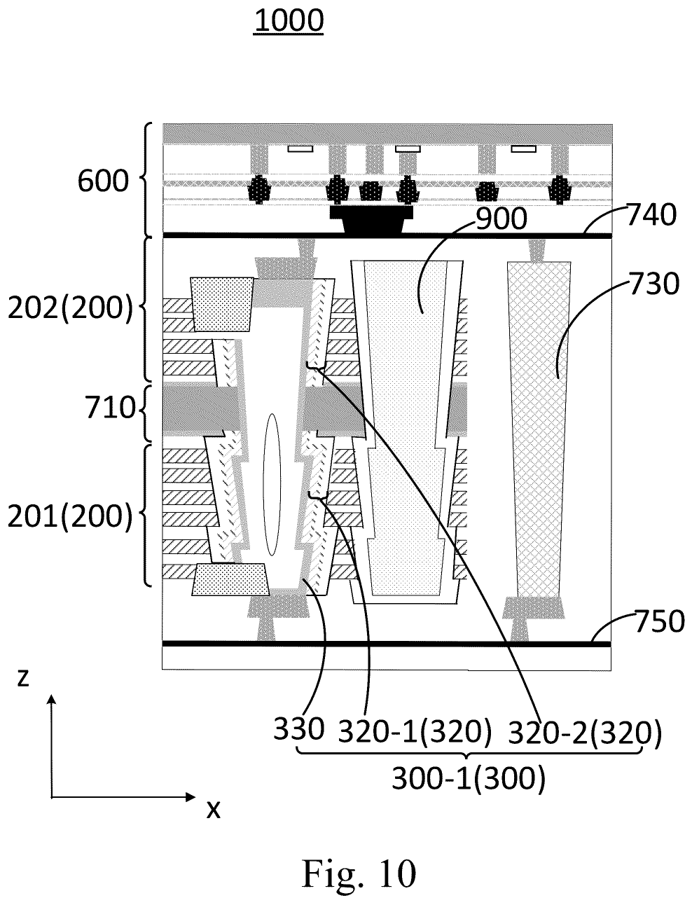

FIG. 10 is a schematic partial cross-sectional view of a semiconductor device 1000 according to an implementation of the present disclosure.

In addition, as shown in FIG. 10, the semiconductor device 1000 may further include a channel structure 300. As an example, the channel structure 300 may include a channel layer 330 and a functional layer 320 surrounding the channel layer 330.

In an example, the semiconductor device 1000 may further include a first semiconductor layer 710. The first semiconductor layer 710 is located between the first sub-stacked structure 201 and the second sub-stacked structure 202 along the z-direction and extends in a direction (e.g., an x-direction) intersecting with the z-direction. The channel layer 330 may extend along the z-direction and be connected with the first semiconductor layer 710. The functional layer 320 may include a first functional layer 320-1 extending along the z-direction in the first sub-stacked structure 201 and a second functional layer 320-2 extending along the z-direction in the second sub-stacked structure 202.

In an example, both the first functional layer 320-1 and the second functional layer 320-2 may include a blocking layer, a charge trapping layer, and a tunneling layer. For example, both the first functional layer 320-1 and the second functional layer 320-2 may include a blocking layer formed on an inner wall of a channel hole (not shown) to block charge flow-out; a charge trapping layer formed on a surface of the blocking layer to store charge during an operation of the semiconductor device; and a tunneling layer formed on a surface of the charge trapping layer.

In some implementations, both the first functional layer 320-1 and the second functional layer 320-2 may include an Oxides Nitride Oxide (ONO) structure. However, in some other implementations, the first functional layer 320-1 and the second functional layer 320-2 may also have a structure different from the ONO configuration. The channel layer 330 can be formed on the surface of the tunneling layer and can be used to transport the desired charge (electrons or holes).

In an example, the channel layer 330 may be made of a semiconductor material such as polysilicon or monocrystalline silicon, and may have a conductive impurity. For example, the channel layer 330 may include an N-type doped or P-type doped polysilicon layer. The channel layer 330 may have a cylindrical or cylindrical shape extending along the z-direction.

In addition, as shown in FIG. 9, as another example, the channel structure 300 may further include a sub-channel structure located in different sub-stacked structures. For example, the channel structure 300 may include a first sub-channel structure 301 located in the first sub-stacked structure 201; a second sub-channel structure 302 located in the second sub-stacked structure 202; and a third sub-channel structure 303 located in the third sub-stacked structure 203, and so on.

The sub-channel structure may include a sub-channel layer and a sub-functional layer surrounding the sub-channel layer. For example, the first sub-channel structure 301 may include a first sub-channel layer 3011 and a first sub-functional layer 3012 surrounding the first sub-channel layer 3011; the second sub-channel structure 302 may include a second sub-channel layer 3021 and a second sub-functional layer 3022 surrounding the second sub-channel layer 3021; and the third sub-channel structure 303 may include a third sub-channel layer 3031 and a third sub-functional layer 3032 surrounding the third sub-channel layer 3031, and so on.

In an example, the semiconductor device 1000 may further include a second semiconductor layer 720. The second semiconductor layer 720 may be located on a side of the sub-stacked structure along the z-direction and extend along a direction (e.g., an x-direction) intersecting with the z-direction, where the second semiconductor layers of the plurality of sub-stacked structures may be connected to each other. For example, the plurality of second semiconductor layers 720 may include: a first sub-semiconductor layer 721 located on a side of the first sub-stacked structure 201 along the z-direction; a second sub-semiconductor layer 722 located on a side of the second sub-stacked structure 202 along the z-direction; and a third sub-semiconductor layer 723 located on a side of the third sub-stacked structure 203 along the z-direction, and the like, where the first sub-semiconductor layer 721, the second sub-semiconductor layer 722, and the third sub-semiconductor layer 723 are connected to each other. As an example, the semiconductor device 1000 may further include a semiconductor layer connection structure 760 extending along the z-direction and penetrating through the plurality of second semiconductor layers 720, thereby connecting the plurality of second semiconductor layers 720 to each other.

In an example, the semiconductor layer connection structure 760 may include a plurality of portions located in different sub-stacked structures, each of which may include a conductive material, such as at least one of tungsten (W), cobalt (Co), copper (Cu), aluminum (Al), doped crystalline silicon, or silicide.

The sub-channel layer may extend along the z-direction into the second semiconductor layer 720. For example, the first sub-channel layer 3011 extends into the first sub-semiconductor layer 721 along the z-direction; the second sub-channel layer 3021 extends into the second sub-semiconductor layer 722 along the z-direction; and the third sub-channel layer 3031 extends into the third sub-semiconductor layer 723 along the z-direction.

In an example, each of the sub-functional layers may include a blocking layer, a charge trapping layer, and a tunneling layer. For example, each of the first sub-functional layer 3012, the second sub-functional layer 3022, and the third sub-functional layer 3032 may include a blocking layer formed on an inner wall of its respective sub-channel hole (not shown) to block charge flow-out; a charge trapping layer formed on a surface of the blocking layer to store charge during an operation of the semiconductor device; and a tunneling layer formed on a surface of the charge trapping layer.

In some implementations, the sub-functional layer may include an ONO structure. However, in some other implementations, the sub-functional layer may also have a structure different from the ONO configuration. The sub-channel layer can be formed on the surface of the tunneling layer and can be used to transport the desired charge (electrons or holes).

In an example, the sub-channel layer may be made of a semiconductor material such as polysilicon or monocrystalline silicon, and may have a conductive impurity. For example, each of the first sub-channel layer 3011, the second sub-channel layer 3021, and the third sub-channel layer 3031 may include an N-type doped or a P-type doped polysilicon layer. In addition, each of the sub-channel layers may have a cylindrical or cylindrical shape extending along the z-direction.

It should be noted that, in order to facilitate the observation of the contact structure 500, the internal structure of the channel structure 300 shown in FIG. 6 and FIG. 7 is omitted, and the channel structure 300 of the local structure of the semiconductor device 1000 shown in FIG. 8 is omitted.

Taking an three-dimensional memory as an example, the channel layer extends in the stacked structure along the stacking direction (for example, the z-direction), and as the number of stacked layers in the stacked structure increases, the distance between the source layer and the drain layer located on both sides of the channel layer along the stacking direction increases, which leads to the reduction of the channel open-circuit current in the operating process of the semiconductor device, which affects the performance of the read operation of the semiconductor device.

As shown in FIG. 10, the first semiconductor layer 710 is located between the first sub-stacked structure 201 and the second sub-stacked structure 202, and is connected with the channel layer 330, so that a portion (hereinafter referred to as a first channel layer) of the channel layer 330 located in the first sub-stacked structure 201 and a portion (hereinafter referred to as a second channel layer) of the channel layer 330 located in the second sub-stacked structure 202 are connected in parallel. In other words, the first semiconductor layer 710 may serve as the drain (or source) of the first channel layer and the second channel layer in the upper and lower sub-stacked structures (the first sub-stacked structure 201 and the second sub-stacked structure 202), and by connecting the first channel layer and the second channel layer in the upper and lower stacked structures in parallel, the channel open-circuit current of the semiconductor device may be improved.

In an example, the first semiconductor layer 710 may be made of a semiconductor material such as polysilicon or monocrystalline silicon, and may have an conductive impurity. As an example, the doping type of the channel layer 330 and the first semiconductor layer 710 may be the same. In addition, a doping concentration of a conductive impurity of the first semiconductor layer 710 may be greater than a doping concentration of a conductive impurity of the channel layer 330. In other words, a drain or a source with a relatively high doping concentration of conductivity impurity can improve the mobility of electrons or holes in the channel, thereby improving the response speed of the semiconductor device.

In addition, the channel layer 330 may further include two ends opposite to each other along the z-direction, the semiconductor device 1000 may further include a channel connection structure 730, and the channel connection structure 730 may connect two ends of the channel layer 330 opposite to each other along the z-direction, so that a portion of the channel layer 330 located in the first sub-stacked structure 201 and a portion of the channel layer 330 located in the second sub-stacked structure 202 are connected together again to form a common source (or drain), so as to achieve the parallel connection of the portion of the channel layer 330 located in the first sub-stacked structure 201 and the portion of the channel layer 330 located in the second sub-stacked structure 202.

For example, the semiconductor device 1000 may further include a first connection layer 740 and a second connection layer 750 connected with the channel connection structure 730, and both the first connection layer 740 and the second connection layer 750 may extend along a direction (for example, an x-direction) intersecting with the z-direction, and connect one end of the channel layer 330 with the channel connection structure 730.

In an example, each of the first connection layer 740, the second connection layer 750, and the channel connection structure 730 may include a conductive material, such as at least one of tungsten (W), cobalt (Co), copper (Cu), aluminum (Al), doped crystalline silicon, or silicide.

As shown in FIG. 9, the sub-channel layers in different sub-stacked structures respectively extend into different sub-semiconductor layers, and the plurality of different sub-semiconductor layers may be connected to each other by the semiconductor layer connection structure. Therefore, the plurality of second semiconductor layers may serve as a common drain (or source) of the sub-channel layers in the sub-stacked structure, so that the sub-channel layers located in different sub-stacked structures are connected in parallel, which may improve the channel open-circuit current of the semiconductor device.

In an example, the second semiconductor layer 720 may be made of a semiconductor material such as polysilicon or monocrystalline silicon, and may have a conductive impurity. As an example, the doping type of the sub-channel layer and the second semiconductor layer 720 may be the same. In addition, the doping concentration of the conductive impurity of the second semiconductor layer 720 may be greater than the doping concentration of the conductive impurity of the sub-channel layer. In other words, a drain or a source with a relatively high doping concentration of conductivity impurity can improve the mobility of electrons or holes in the channel, thereby improving the response speed of the semiconductor device.

As shown in FIGS. 7-10, in some implementations of the present disclosure, the semiconductor device 1000 may further include a peripheral circuit structure 600. The semiconductor device 1000 may include a memory array, where the memory array may include a channel structure 300 and a contact structure 500. The peripheral circuit structure 600 may be understood as an operating circuit. In an example, the peripheral circuit structure 600 may include any suitable digital, analog, and/or mixed signal circuit for facilitating the operation of the memory array in the semiconductor device 1000. For example, the peripheral circuit structure 600 may include one or more of a page buffer, a decoder (e.g., a row decoder and a column decoder), a sensing structure (e.g., a bit line sensing amplification structure), a driving structure (e.g., a word line driving structure), an input/output circuit, a charge pump, a voltage source or generator, a current or voltage reference, any portion (e.g., sub-circuit) of the foregoing functional circuit, or any active or passive component (e.g., a transistor, a diode, a resistor, or a capacitor) of a circuit, which is not limited in the present disclosure.

In some implementations of the present disclosure, the stacked structure 200 may comprise two sides opposite to each other along the z-direction, for example, the first side 200-1 and the second side 200-2. In an example, the peripheral circuit structure 600 may be disposed on at least one of the first side 200-1 and the second side 200-2.

In addition, as shown in FIG. 9, in some implementations of the present disclosure, the second semiconductor layer 720 may be located on a side of the sub-stacked structure away from the peripheral circuit structure 600 along the z-direction. For example, the peripheral circuit structure 600 may be disposed on at least one of the first side 200-1 and the second side 200-2 of the stacked structure 200. Taking the peripheral circuit structure 600 being located on the first side 200-1 as an example, the first sub-semiconductor layer 721 may be located on a side of the first sub-stacked structure 201 away from the peripheral circuit structure 600; the second sub-semiconductor layer 722 may be located on a side of the second sub-stacked structure 202 away from the peripheral circuit structure 600; and the third sub-semiconductor layer 723 may be located on a side of the third sub-stacked structure 203 away from the peripheral circuit structure 600, and so on.

In addition, referring again to FIGS. 7-10, in some implementations of the present disclosure, the peripheral circuit structure 600 may be connected with the stacked structure 200 by bonding. In this implementation, the semiconductor device 1000 may further comprise a wafer connection structure 800 extending through the bonding layer along the z-direction. In an example, the wafer connection structure 800 may include a vertical interconnection channel. By adopting the vertical interconnection channel, the transmission speed of the input/output between the two bonded wafers can be improved; for example, the connection part 801 of the contact structure 500 is connected with the wafer connection structure 800 between two bonded wafers.

In an example, as shown in FIG. 8, the peripheral circuit structure 600 may include a first peripheral circuit 601 and a second peripheral circuit 602. The first peripheral circuit 601 may be disposed on the first side 200-1 of the stacked structure 200, and the second peripheral circuit 602 may be disposed on the second side 200-2 of the stacked structure 200.

It should be noted that, in the drawings of the present disclosure, the structure, number and position of the peripheral circuit and the interconnection structure (for example, the interconnection layer, the interconnection path and the interconnection line) are shown only by an illustration, but it is to be understood that the implementation of the peripheral circuit and the interconnection structure shown in the figures and related content herein is only for ease of illustration and is not limited in the present disclosure. Those skilled in the art can adjust the implementation of the peripheral circuit and the interconnection structure according to the idea of the disclosure to achieve the same technical effect.

Referring again to FIGS. 1-6, the contact structure 500 may penetrate through the stair step 411 along the z-direction and be connected with the gate layer 210, thereby achieving the connection between the gate layer 210 and the peripheral circuit structure 600.

As an example, in a case where the stacked structure 200 includes a plurality of sub-stacked structures, the contact structures 500 may penetrate through the stair steps 411 along the z-direction, and are connected with the gate layers of different sub-stacked structures. For example, the stacked structure 200 shown in FIG. 6 may include a first sub-stacked structure 201 and a second sub-stacked structure 202, where the contact structure 500 may penetrate through the stair steps 411 along the z-direction and be connected with both the first gate layer 210-1 of the first sub-stacked structure 201 and the second gate layer 210-2 of the second sub-stacked structure 202.

Therefore, in this implementation, the connection between the gate layers of different sub-stacked structures and the peripheral circuit can also be achieved through the same contact structure while the area of the region where the stair step is located is effectively reduced, the number of contact structures in the semiconductor device is reduced, the manufacturing process of the contact structure is simplified while the storage density of the semiconductor device is improved, and the manufacturing cost of the semiconductor device is reduced.

In an example, as shown in FIGS. 1-4, a shape of a cross-section of the stair unit structure 400 in a plane (for example, an x-y plane, where both the x-direction and the y-direction intersect with the z-direction) intersecting with the z-direction may include at least one of a circle, an ellipse, a polygon, and a sector.

Further, the shape of the cross-section of the stair step 411 in a plane (e.g., an x-y plane) intersecting with the z-direction may include an annular shape. For example, the annular shape may include at least one of a circular ring, an elliptical ring, a polygonal ring, and a sector ring.

Referring to FIGS. 1-5, as an example, the plurality of stair unit structures 400 may have a different number of stair steps 411. For example, the plurality of stair unit structures 400 shown in FIG. 1 include a first stair unit structure 410 and a second stair unit structure 420, where the first stair unit structure 410 has 3 stair steps 411 of a circular ring shape, and the second stair unit structure 420 has 2 stair steps 411 of a circular ring shape. In addition, as shown in FIG. 5, the first stair unit structure 410 and the second stair unit structure 420 may each have a plurality of stair steps 411 of a sector ring shape, where the first stair unit structure 410 and the second stair unit structure 420 may have different numbers of stair steps 411. It should be noted that the number of the stair steps is not limited to the number shown in the figures, and may be further set as required, which is not limited in the present disclosure.

In addition, with reference to FIG. 5 and FIG. 6, the distance from the stair step 411 of the stair unit structure 400 to the surface of the stack cover layer 2021 of the stacked structure 200 along the z-direction may be different; or the distance from the stair step 411 of the stair unit structure 400 to the surface of the stack isolating layer 2022 of the stacked structure 200 along the z-direction may be different. For example, a distance from one of the plurality of stair steps 411 of the first stair unit structure 410 to the stack cover layer 2021 may be a first distance h1, a second distance h2, and a third distance h3, respectively; and a distance from one of the plurality of stair steps 411 of the second stair unit structure 420 to the stack cover layer 2021 may be a fourth distance h4, a fifth distance h5, respectively; and so on.

In addition, a distance between the stair steps 411 of the plurality of stair unit structures 400 and one of the two surfaces of the stacked structure 200 along the z-direction may be different. For example, a distance from one of the plurality of stair steps 411 of the first stair unit structure 410 to the stack cover layer 2021 may be different from a distance from one of the plurality of stair steps 411 of the second stair unit structure 420 to the stack cover layer 2021. That is, the first distance h1, the second distance h2, the third distance h3, the fourth distance h4, and the fifth distance h5 may be different from each other.

As shown in FIGS. 1-4, as an example, in a direction (for example, an x-direction and a y-direction) intersecting with the z-direction, the plurality of stair steps 411 of the same stair unit structure 400 may have different sizes. In addition, as another example, the plurality of stair steps 411 of the same stair unit structure 400 may also have the same size. It should be noted that the size of the stair step in the direction intersecting with the z-direction may be understood as the size of the exposed step surface of the stair step.

For example, taking the first stair unit structure 410 shown in FIG. 1 as an example, the size of one stair step 411 of the first stair unit structure 410 in the direction intersecting with the z-direction is d1, and the size of another stair step 411 of the first stair unit structure 410 in the direction intersecting with the z-direction is d2, where the size d1 is greater than the size d2. Taking the second stair unit structure 420 shown in FIG. 3 as an example, each of the sizes of the plurality of stair steps 411 of the second stair unit structure 420 in the direction intersecting with the z-direction may be d3. Taking the second stair unit structure 420 shown in FIG. 4 as an example, each of the sizes of the plurality of stair steps 411 of the second stair unit structure 420 in the direction intersecting with the z-direction may be d4.

In addition, with reference to FIG. 5 and FIG. 7, in some implementations of the present disclosure, lengths of the plurality of stair steps 411 may increase from the first side 200-1 of the stacked structure 200 to the second side 200-2 of the stacked structure 200, where the length may be understood as a size of the stair step 411 in a direction (for example, an x-direction) intersecting with the z-direction. For example, the lengths of two different stair steps 411 in the first sub-stacked structure 201 may be a first length L1 and a second length L2, respectively, where the second length L2 is greater than the first length L1. In other words, the lengths of the plurality of stair steps 411 of the first sub-stacked structure 201 may increase from the first side 200-1 of the stacked structure 200 to the second side 200-2 of the stacked structure 200. Similarly, the lengths of the plurality of stair steps 411 of the remaining sub-stacked structures such as the second sub-stacked structure 202 may also increase from the first side 200-1 of the stacked structure 200 to the second side 200-2 of the stacked structure 200. In this implementation, the peripheral circuit structure 600 may be disposed on the first side 200-1. In other words, the lengths of the plurality of stair steps 411 of the stacked structure 200 may increase towards a direction away from the peripheral circuit structure 600, which may be, for example, a z+direction opposite to the z-direction. In addition, as an example, the lengths of the plurality of stair steps 411 of the stacked structure 200 may also decrease in a direction away from the peripheral circuit structure 600. In other words, the lengths of the plurality of stair steps 411 of the stacked structure 200 may also decrease from the first side 200-1 of the stacked structure 200 to the second side 200-2 of the stacked structure 200.

In addition, referring to FIGS. 2-5, in some implementations of the present disclosure, the stair unit structure 400 may include a plurality of sub-regions, such as a first sub-region 401, a second sub-region 402, a third sub-region 403, a fourth sub-region 404, and so on. In an example, each sub-region may include a plurality of stair steps 411.

As an example, the plurality of sub-regions may have a different number of stair steps 411. For example, the first stair unit structure 410 shown in FIG. 3 may include a first sub-region 401, a second sub-region 402, a third sub-region 403, and a fourth sub-region 404, where the first sub-region 401 and the fourth sub-region 404 may have 4 stair steps 411; and the second sub-region 402 and the third sub-region 403 may have 3 stair steps 411. As another example, the plurality of sub-regions may also have the same number of stair steps 411. For example, the first stair unit structure 410 shown in FIG. 2 may include a first sub-region 401, a second sub-region 402, a third sub-region 403, and a fourth sub-region 404, where each of the first sub-region 401, the second sub-region 402, the third sub-region 403, and the fourth sub-region 404 has 4 stair steps 411. In addition, the number of the stair steps of each sub-region is not limited to the number of layers shown in the figure, and may be further set as required, which is not limited in the present disclosure.

In addition, as shown in FIG. 5 and FIG. 6, distances between the plurality of sub-regions and the surface of the stack cover layer 2021 of the stacked structure 200 in the z-direction are different; in addition, distances between the plurality of sub-regions and the surface of the stack isolating layer 2022 of the stacked structure 200 in the z-direction are also different. In other words, the plurality of sub-regions may have different depths in the z-direction. Taking the first stair unit structure 410 as an example, it has a plurality of sub-regions, such as a first sub-region 401, a second sub-region 402, a third sub-region 403, and so on. Assuming that the distance between the surface of the stack cover layer 2021 and the surface of the stair step of the sub-region at the highest stacked position in the stacked structure 200 is the distance therebetween, the distance between the first sub-region 401 and the surface of the stack cover layer 2021 is the third distance h3; and the distance between the third sub-region 403 and the surface of the stack cover layer 2021 is the sixth distance h6, where the third distance h3 and the sixth distance h6 may be different.

Referring again to FIGS. 5 and 6, distances between the stair steps 411 of the plurality of sub-regions and the surface of the stack cover layer 2021 of the stacked structure 200 in the z-direction are different. In addition, distances between the stair steps 411 of the plurality of sub-regions and the surface of the stack isolating layer 2022 of the stacked structure 200 in the z-direction are also different. For example, each of the distances between the stair step 411 of the first sub-region 401, the stair step 411 of the second sub-region 402, and the stair step 411 of the third sub-region 403 shown in FIG. 5 and the surface of the stack cover layer 2021 of the stacked structure 200 in the z-direction may be different.

Taking the stair step (hereinafter referred to as the highest stair step) of each of the above described sub-regions at the highest stacked location in the stacked structure 200 as an example, the distance between the highest stair step in the first sub-region 401 and the surface of the stack cover layer 2021 in the z-direction is a third distance h3, and the distance between the highest stair step in the third sub-region 403 and the surface of the stack cover layer 2021 in the z-direction is a sixth distance h6, where the third distance h3 is different from the sixth distance h6.

Taking a stair step (hereinafter referred to as a second stair step) closest to the highest stair step in each of the above described sub-regions as an example, the distance between the second stair step in the first sub-region 401 and the surface of the stack cover layer 2021 in the z-direction is a second distance h2, and the distance between the second stair step in the third sub-region 403 and the surface of the stack cover layer 2021 in the z-direction is a first distance h1, where the second distance h2 is different from the first distance h1. In addition, the first distance h1, the second distance h2, the third distance h3, and the sixth distance h6 may also be different.

Therefore, in some implementations of the present disclosure, the layout of the stair step and the sub-region in the stair unit structure may be selected according to different settings of the semiconductor device architecture, which may effectively reduce the area of the region where the stair step is located, thereby improving the storage density of the semiconductor device.

As shown in FIG. 8, the contact structure 500 may include a plurality of portions located in different sub-stacked structures. For example, the contact structure 500 may include a first portion 501 located in the first sub-stacked structure 201 and a second portion 502 located in the second sub-stacked structure 202, and so on. In addition, the contact structure 500 further includes a portion located in the first semiconductor layer 710 or the second semiconductor layer 720 (as shown in FIG. 9). It should be noted that throughout the present disclosure, only for ease of description, the contact structure 500 is divided into a plurality of portions, and the portions are named separately. It should be understood by those skilled in the art that the contact structure 500 is actually an integral structure in which there are no obvious boundaries between the plurality of portions.

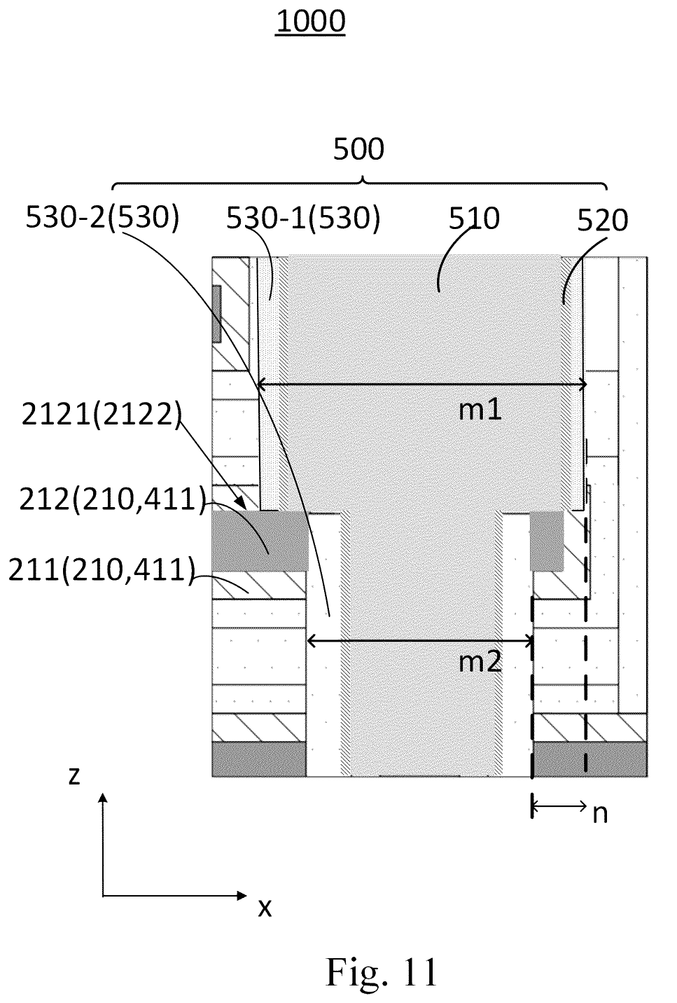

FIG. 11 is a schematic partial cross-sectional view of a semiconductor device 1000 according to an implementation of the present disclosure.

As shown in FIG. 8 and FIG. 11, in some implementations of the present disclosure, a portion of the contact structure 500 located in the sub-stacked structure may include a first contact portion and a second contact portion, where the first contact portion may extend along the z-direction to a surface of the gate layer 210 and be connected with the surface, and the second contact portion may be connected with the first contact portion and penetrate through the stair step 411 along the z-direction.

For example, the first portion 501 includes a first contact portion 501-1 located in the first sub-stacked structure 201 and a second contact portion 501-2 located in the first sub-stacked structure 201 (hereinafter referred to as a first sub-contact portion 501-1 and a second sub-contact portion 501-2); and the second portion 502 includes a first contact portion 502-1 located in the second sub-stacked structure 202 and a second contact portion 502-2 located in the second sub-stacked structure 202 (hereinafter referred to as a third sub-contact portion 502-1 and a fourth sub-contact portion 502-2).

In an example, the first sub-contact portion 501-1 extends along the z-direction to the surface 2121 of the first gate layer 210-1 and is connected with the surface 2121, and the second sub-contact portion 501-2 may be connected with the first sub-contact portion 501-1 and penetrate through the stair step 411 along the z-direction. The third sub-contact portion 502-1 extends along the z-direction to the surface 2122 of the second gate layer 210-2 and is connected with the surface 2122, and the fourth sub-contact portion 502-2 may be connected with the third sub-contact portion 502-1 and penetrate through the stair step 411 along the z-direction.

It should be noted that FIG. 11 shows the internal structure of the contact structure 500 and the gate layer 210, and for ease of observation, the contact structure 500 and the gate layer 210 shown in FIG. 11 adopt different patterns from the contact structure 500 and the gate layer 210 shown in the rest of figures.

Further, in conjunction with FIGS. 7 and 8, a portion of the first contact portion extending to the surface of the gate layer 210 may extend in a direction (e.g., an x-direction) intersecting with the z-direction. For example, the semiconductor device 1000 further includes a cover dielectric layer 240′ covering the above surface, and the portion of the first contact portion extending to the above surface is located in the cover dielectric layer 240′ and extends in a direction (for example, an x-direction) intersecting with the z-direction. In an example, the first sub-contact portion 501-1 extends along the z-direction to the surface 2121 of the first gate layer 210-1, and the portion of the first sub-contact portion 501-1 extending to the surface 2121 may extend along a direction (e.g., an x-direction) intersecting with the z-direction. The third sub-contact portion 502-1 extends along the z-direction to the surface 2122 of the second gate layer 210-2, and the portion of the third sub-contact portion 502-1 extending to the surface 2122 may extend along a direction (e.g., the x-direction) intersecting with the z-direction. This increases the contact area between the first contact portion and the gate layer, thereby improving the reliability of connection between the first contact portion and the gate layer.

In an example, the cover dielectric layer 240′ may include any suitable insulating dielectric material layer. For example, the cover dielectric layer 240′ may include a silicon nitride layer. In addition, as an example, as shown in FIGS. 8 and 11, a shape of a cross-section of a portion of the contact structure 500 located in different sub-stacked structures, such as the first portion 501 and the second portion 502, in the x-z plane may include a wedge shape. For example, in a direction (e.g., an x-direction) intersecting with the z-direction, a size of a “wedge” portion of the contact structure 500 may be a first size m1, and a size of a remaining portion of the contact structure 500 may be a second size m2, where the first size m1 is greater than the second size m2.

In an example, the gate layer 210 may be connected with the peripheral circuit structure 600 through the first contact portion or the second contact portion of the contact structure 500. For example, the first gate layer 210-1 may be connected with the peripheral circuit structure 600 through the first sub-contact portion 501-1 or the second sub-contact portion 501-2; and the second gate layer 210-2 may be connected with the peripheral circuit structure 600 through the third sub-contact portion 502-1 or the fourth sub-contact portion 502-2.

In addition, the peripheral circuit structure 600 may include a first peripheral circuit 601 and a second peripheral circuit 602. The first peripheral circuit 601 may be disposed on the first side 200-1 of the stacked structure 200, and the second peripheral circuit 602 may be disposed on the second side 200-2 of the stacked structure 200. In this implementation, the first contact portion is closer to the first peripheral circuit 601 located on the first side 200-1 than the second contact portion, and the second contact portion is closer to the second peripheral circuit 602 located on the second side 200-2 than the first contact portion. Therefore, the gate layer 210 may be connected with the first peripheral circuit 601 through the first contact portion of the contact structure 500, or connected with the second peripheral circuit 602 through the second contact portion of the contact structure 500. For example, the first gate layer 210-1 may be connected with the first peripheral circuit 601 through the first sub-contact portion 501-1, or connected with the second peripheral circuit 602 through the second sub-contact portion 501-2; and the second gate layer 210-2 may be connected with the first peripheral circuit 601 through the third sub-contact portion 502-1, or be connected with the second peripheral circuit 602 through the fourth sub-contact portion 502-2.

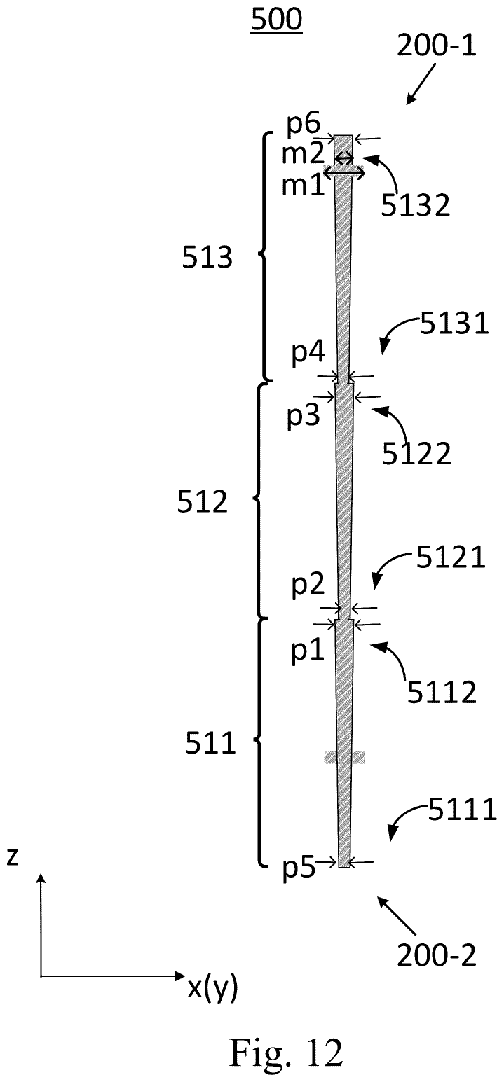

FIG. 12 is a schematic cross-sectional view of a contact structure 500 according to an implementation of the present disclosure.

With reference to FIG. 8 and FIG. 12, in some implementations of the present disclosure, the contact structure 500 may include a first sub-portion 511, a second sub-portion 512, and a third sub-portion 513 connected to each other along the z-direction, where the first sub-portion 511 and a portion of the second sub-portion 512 are located in the first sub-stacked structure 201, and the other portion of the second sub-portion 512 and the third sub-portion 513 are located in the second sub-stacked structure 202.

In an example, the second sub-portion 512 is closer to the first side 200-1 where the peripheral circuit structure 600 is located than the first sub-portion 511, the first end 5112 of the first sub-portion 511 is connected with the second end 5121 of the second sub-portion 512, and in a direction (for example, the x-direction, the y-direction) intersecting with the z-direction, a size p1 of the first end 5112 is greater than a size p2 of the second end 5121. In addition, the third sub-portion 513 is closer to the first side 200-1 where the peripheral circuit structure 600 is located than the second sub-portion 512, the third end 5122 of the second sub-portion 512 is connected with the fourth end 5131 of the third sub-portion 513, and in a direction (for example, the x-direction, the y-direction) intersecting with the z-direction, the size p3 of the third end 5122 is larger than the size p4 of the fourth end 5131.

In addition, at least one of the first sub-portion 511, the second sub-portion 512, and the third sub-portion 513 may include an end and the other end opposite to each other along the z-direction, the end is closer to the first side 200-1 where the peripheral circuit structure 600 is located than the other end, and in a direction (for example, the x-direction, the y-direction) intersecting with the z-direction, the size of the end may be greater than the size of the other end. For example, the first sub-portion 511 further includes a fifth end 5111 opposite to the first end 5112 in the z-direction, where the first end 5112 is closer to the first side 200-1 than the fifth end 5111, and in a direction (e.g., the x-direction, the y-direction) intersecting with the z-direction, the size p1 of the first end 5112 is greater than the size p5 of the fifth end 5111. The third end 5122 of the second sub-portion 512 is closer to the first side 200-1 than the second end 5121, and in a direction (e.g., the x-direction, the y-direction) intersecting with the z-direction, the size p3 of the third end 5122 is greater than the size p2 of the second end 5121. The third sub-portion 513 further includes a sixth end 5132 opposite to the fourth end 5131 in the z-direction, where the sixth end 5132 is closer to the first side 200-1 than the fourth end 5131, and in a direction (e.g., the x-direction, the y-direction) intersecting with the z-direction, the size p6 of the sixth end 5132 is greater than the size p4 of the fourth end 5131.

In addition, referring to FIG. 8 and FIG. 11, in some implementations of the present disclosure, the contact structure 500 may include a conductive core layer 510, an adhesive layer 520, and a blocking layer 530, where the adhesive layer 520 surrounds the conductive core layer 510; the blocking layer 530 surrounds the adhesive layer 520, and includes a first sub-layer 530-1 and a second sub-layer 530-2 spaced apart from each other in a direction (e.g., the x-direction) intersecting with the z-direction. In an example, in a direction (e.g., the x-direction) intersecting with the z-direction, there may be a first spacing n between the first sub-layer 530-1 and the second sub-layer 530-2.

In an example, the conductive core layer 510 may include any or a combination of a conductive metal material and a doped semiconductor material, where the conductive metal material may be, for example, tungsten (W), cobalt (Co), copper (Cu), aluminum (Al), or the like, and the doped semiconductor material may be, for example, doped crystalline silicon or silicide, which is not limited in the present disclosure. The adhesive layer 520 may include, but is not limited to, titanium, titanium nitride, tantalum, tantalum nitride, or the like. The adhesive layer is used to block the diffusion of ions in the conductive core layer and improve the adhesive force between the conductive core layer and the blocking layer. The blocking layer 530 may include any suitable dielectric material, such as silicon oxide, silicon nitride, silicon oxynitride, or a high-k dielectric. In addition, the first sub-layer 530-1 and the second sub-layer 530-2 of the blocking layer 530 may include different insulating dielectric materials.

Referring again to FIGS. 5, 9 and 10, in some implementations of the present disclosure, the semiconductor device 1000 may further include a gate line isolation structure 900 penetrating through the stacked structure 200 along the z-direction. In addition, the gate line isolation structure 900 may also extend in the stacked structure 200 along the y-direction intersecting with both the x-direction and the z-direction.

In an example, the gate line isolation structure 900 may include a gate line isolation layer and a gate line filling layer surrounded by the gate line isolation layer. In an example, a material of the gate line isolation layer may include at least one of a high-k dielectric layer and an insulating dielectric material layer such as a silicon oxide layer. In addition, a material of the gate line filling layer may include at least one of a semiconductor material such as polysilicon, and an insulating dielectric material layer such as silicon oxide, silicon nitride, and silicon oxynitride. In an example, the material of the gate line filling layer may further include a conductive material layer. The inner filling material of the gate line isolation structure 900 is not limited in the present disclosure.

Therefore, according to the semiconductor device provided by at least one implementation of the present disclosure, the stair unit structure of the semiconductor device is located in the stacked structure and includes a plurality of wrapping-around stair steps. By the wrapping-around stair steps, the area where the stair steps are located can be reduced while the contact structure and the gate layer are effectively connected, thereby improving the storage density of the semiconductor device.

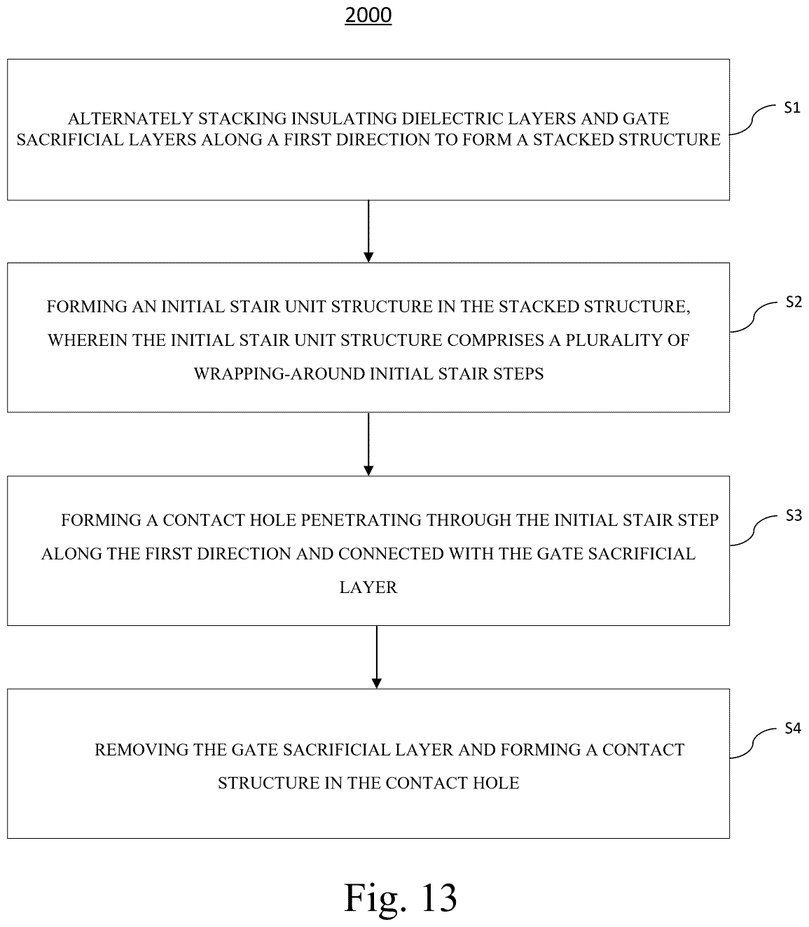

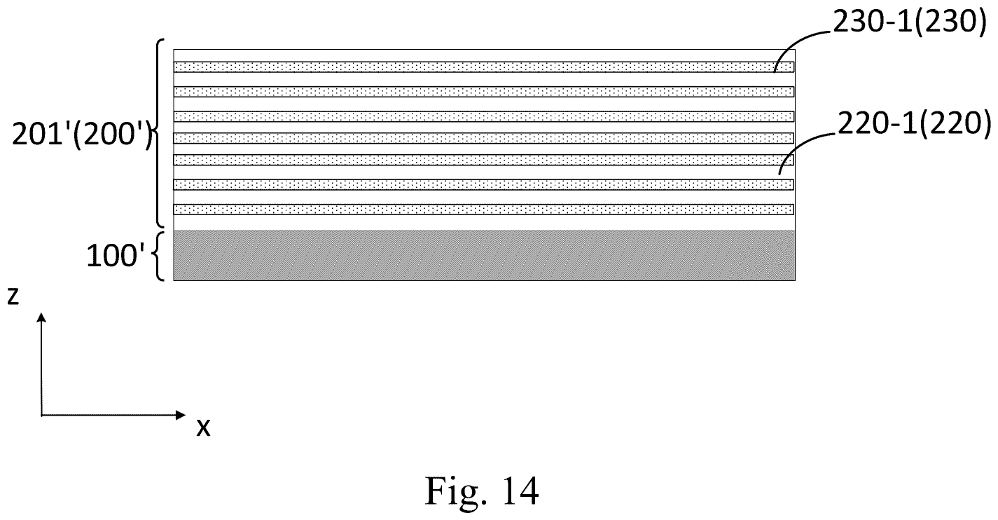

FIG. 13 is a flowchart of a method of manufacturing 2000 of a semiconductor device according to an implementation of the present disclosure. FIGS. 14-32 are schematic process diagrams of a method of manufacturing 2000 of a semiconductor device according to an implementation of the present disclosure.

As shown in FIG. 13, the method of manufacturing 2000 of a semiconductor device may include operations S1-S4. At operation S1, the method may include alternately stacking insulating dielectric layers and gate sacrificial layers along a first direction to form a stacked structure; at operation S2, the method may include forming an initial stair unit structure in the stacked structure, where the initial stair unit structure includes a plurality of wrapping-around initial stair steps; at operation S3, the method may include forming a contact hole penetrating through the initial stair step along the first direction and connected with the gate sacrificial layer; and at operation S4, the method may include removing the gate sacrificial layer, and forming a contact structure in the contact hole.

The process of each operation of the above method of manufacturing 2000 in the implementations of the present disclosure will be described in detail below with reference to FIGS. 14-32.

### Operation S1

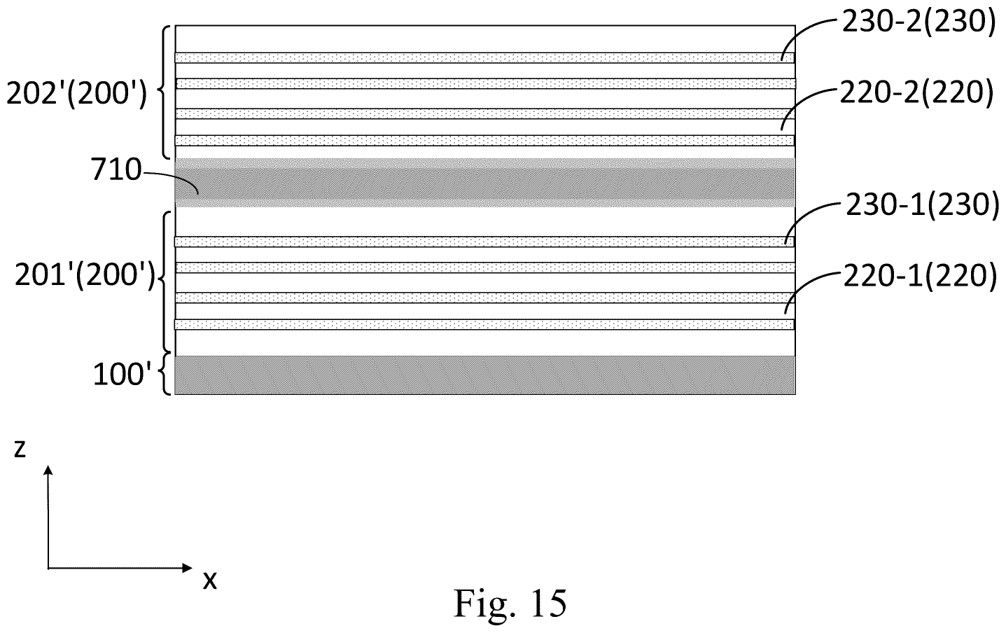

FIG. 14 is a schematic top view of a structure formed after forming the stacked structure 200′ according to one implementation of the present disclosure. FIG. 15 is a schematic top view of a structure formed after forming the stacked structure 200′ according to another implementation of the present disclosure.

The following description will take a manufacturing process in a single-stacking manner or a double-stacking manner as an example to describe the formation process of the stacked structure 200′. However, since the content and structure involved in the above manufacturing process may be completely or partially applicable to the formation process of the stacked structure including the plurality of sub-stacked structures, the contents related to or similar thereto are not described again. However, those skilled in the art may understand that subsequent fabrication processes may be performed on the basis of a single-stacking configuration, a double-stacking configuration, or a multi-stacking configuration, where the number of the sub-stacked structures in the multi-stacking structure is greater than 2.

In an example, as shown in FIG. 14, in some implementations of the present disclosure, before the stacked structure 200′ is formed, the method of manufacturing 2000 of the semiconductor device further includes providing an initial substrate 100′.

As an example, the initial substrate 100′ may be made of any suitable semiconductor material, such as monocrystalline silicon (Si), monocrystalline germanium (Ge), silicon germanium (GeSi), silicon carbide (SiC), silicon-on-insulator (SOI), germanium-on-insulator (GOI), or a III-V compound, such as gallium arsenide. In addition, the initial substrate 100′ may use single crystal silicon.

In an implementation of the present disclosure, the initial substrate 100′ may be, for example, a composite substrate for supporting a device structure thereon. A plurality of layers made of different materials may be sequentially disposed by a thin film deposition process such as Chemical Vapor Deposition (CVD), Physical Vapor Deposition (PVD), Atomic Layer Deposition (ALD), or any combination thereof to form the initial substrate 100′.

The initial substrate 100′ may include a substrate sacrificial layer. The substrate sacrificial layer may include a single layer, multiple layers, or a suitable composite layer. For example, the substrate sacrificial layer may include any one or more of a silicon oxide layer, a silicon nitride layer, and a silicon oxynitride layer. As an example, the substrate sacrificial layer may be a high dielectric constant layer. As another example, the substrate sacrificial layer may include a dielectric layer, a sacrificial layer and a dielectric layer that are sequentially disposed, where the dielectric layer may be a silicon nitride layer, and the sacrificial layer may be a silicon oxide layer. As another example, the substrate sacrificial layer may include any one or more of a dielectric material, a semiconductor material, and a conductive material. For example, the sacrificial layer may be single crystal silicon or polysilicon. In an example, in an implementation of the present disclosure, the exemplary material for forming the sacrificial layer may be polysilicon.

A partial region of the initial substrate 100′ may also be formed to a well region formed of N-type or P-type dopants via an ion implantation or diffusion process. The dopant may include at least one of phosphorus (P), arsenic (As), and antimony (Sb). In some implementations of the present disclosure, the well regions may be made of the same dopant, or the well regions may be made of different dopants, and the doping concentration of the well regions may be the same or different, which is not limited in the present disclosure.

After forming the initial substrate 100′, the insulating dielectric layer 220 and the gate sacrificial layer 230 may be alternately stacked on one side of the initial substrate 100′ along the z-direction to form a stacked structure 200′ by one or more thin film deposition processes, which may include, but are not limited to, Chemical Vapor Deposition (CVD), Physical Vapor Deposition (PVD), Atomic Layer Deposition (ALD), or any combination thereof.

The stacked structure 200′ may include only a single sub-stacked structure, such as the first sub-stacked structure 201′. The first sub-stacked structure 201′ may include a plurality of pairs of the first insulating dielectric layer 220-1 and the first gate sacrificial layer 230-1 stacked alternately with each other. In other words, the first sub-stacked structure 201′ may include a plurality of pairs of dielectric layers, such as 64 pairs, 128 pairs, or more than 128 pairs of the first insulating dielectric layers 220-1 and the first gate sacrificial layers 230-1.

In some implementations of the present disclosure, the first insulating dielectric layer 220-1 and the first gate sacrificial layer 230-1 may respectively include a first insulating material and a second insulating material different from the first insulating material. Exemplary materials for forming the first insulating dielectric layer 220-1 and the first gate sacrificial layer 230-1 may include silicon oxide and silicon nitride, respectively. The silicon oxide layer may serve as an isolation stack layer, while the silicon nitride layer may serve as a sacrificial stack layer. The sacrificial stack layer may then be etched away, and may be replaced with a conductor layer including a conductive material, thereby forming a gate layer of the semiconductor device.

As shown in FIG. 14 and FIG. 15, after the first sub-stacked structure 201′ is formed, a stacked structure 200′ may be formed by a plurality of sub-stacked structures sequentially stacked in the z-direction by using a double-stacking technique or a multi-stacking technique, where each sub-stacked structure may include a plurality of pairs of stacked dielectric layers. The number of layers of each sub-stacked structure may be the same or different.

In an example, the second sub-stacked structure 202′ may be formed on a side of the first sub-stacked structure 201′ by one or more thin film deposition processes, which may include, but are not limited to, Chemical Vapor Deposition (CVD), Physical Vapor Deposition (PVD), Atomic Layer Deposition (ALD), or any combination thereof.

The second sub-stacked structure 202′ may include a plurality of pairs of the second insulating dielectric layer 220-2 and the second gate sacrificial layer 230-2 stacked alternately with each other. The second insulating dielectric layer 220-2 and the second gate sacrificial layer 230-2 may include a third insulating material and a fourth insulating material different from the third insulating material, respectively. Exemplary materials for forming the second insulating dielectric layer 220-2 and the second gate sacrificial layer 230-2 may include silicon oxide and silicon nitride, respectively. In addition, the second sub-stacked structure 202′ may include a plurality of pairs of dielectric layers, such as 64 pairs, 128 pairs, or more than 128 pairs of second insulating dielectric layers 220-2 and second gate sacrificial layers 230-2.

In addition, in some implementations of the present disclosure, before the second sub-stacked structure 202′ is formed, a first semiconductor layer 710 may be further formed on a side of the first sub-stacked structure 201′ away from the initial substrate 100′.

In an example, the first semiconductor layer 710 may be formed by one or more thin film deposition processes, which may include, but are not limited to, Chemical Vapor Deposition (CVD), Physical Vapor Deposition (PVD), Atomic Layer Deposition (ALD), or any combination thereof.

The material of the first semiconductor layer 710 may include a semiconductor material such as polysilicon or monocrystalline silicon. In addition, the first semiconductor layer 710 may further include an N-type doped or P-type doped conductive impurity. The first semiconductor layer 710 may extend along a direction (e.g., an x-direction) intersecting with the z-direction. After the first semiconductor layer 710 is formed, the second sub-stacked structure 202′ may be formed by the above method. In other words, the first semiconductor layer 710 is located between the first sub-stacked structure 201′ and the second sub-stacked structure 202′ along the z-direction.

### Operation S2

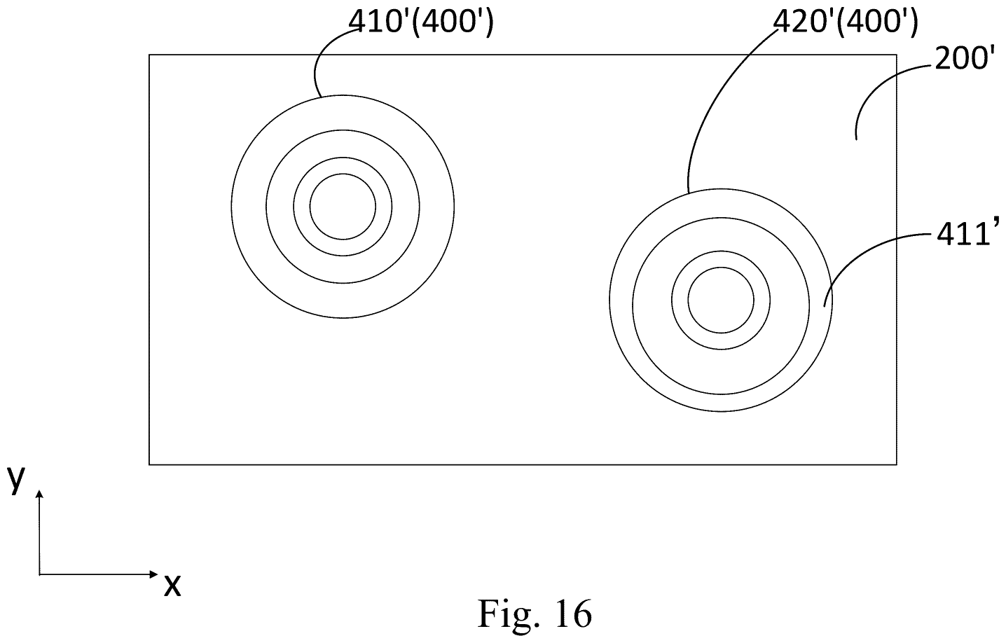

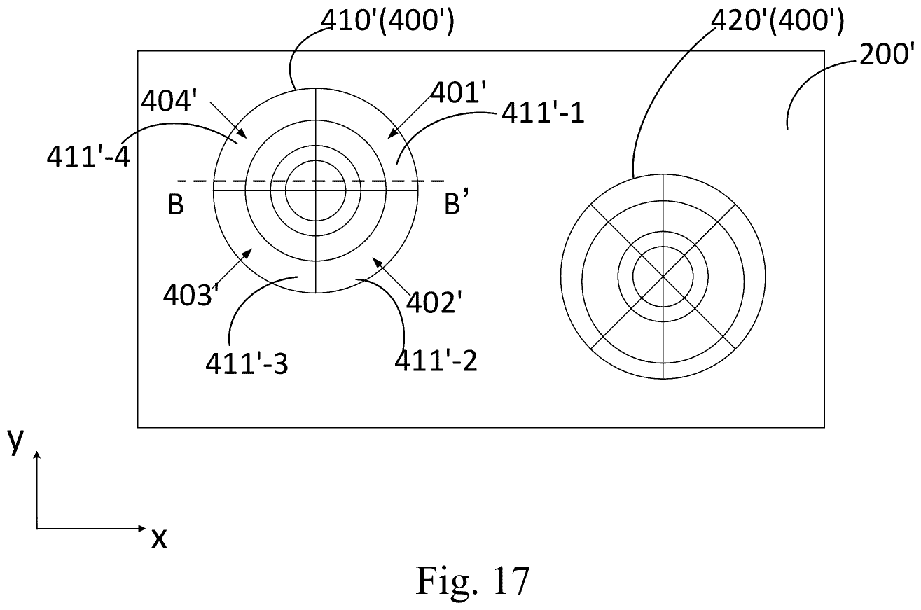

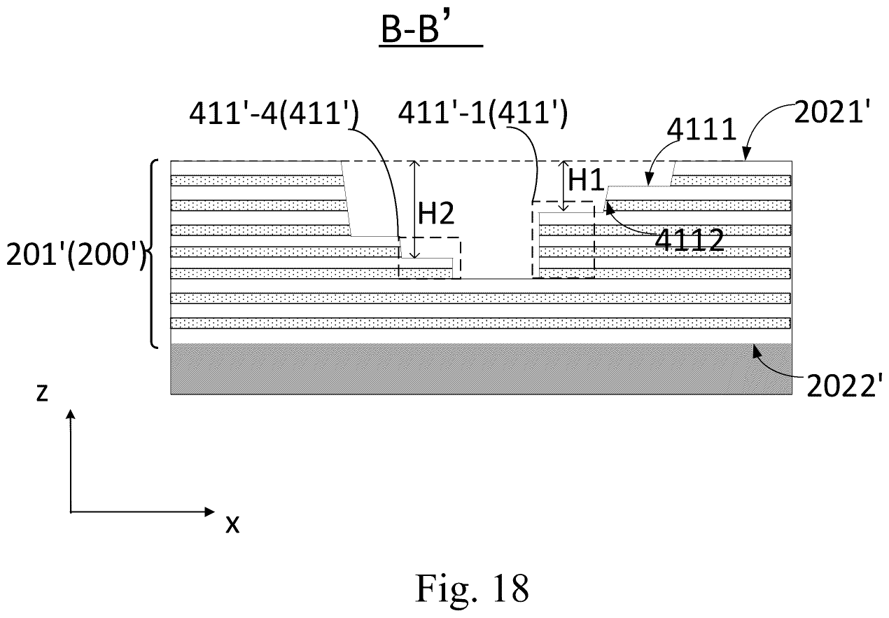

FIG. 16 is a schematic top view of a structure formed after the initial stair unit structure 400′ is formed according to an implementation of the present disclosure. FIG. 17 is a schematic top view of a structure formed after the initial stair unit structure 400′ is formed according to another implementation of the present disclosure. FIG. 18 is a schematic cross-sectional view of the structure shown in FIG. 17 taken along line B-B′.

As shown in FIGS. 14-18, in some implementations of the present disclosure, the operation S2 of forming an initial stair unit structure in the stacked structure, where the initial stair unit structure includes a plurality of wrapping-around initial stair steps, may, for example, include: performing a plurality of “trim-etch” cycles on a predetermined portion of the stacked structure 200′, such that the predetermined portion of the stacked structure 200′ has one or more sloped edges and a top (away from the initial substrate 100′) dielectric layer pair that is shorter than the bottom (closer to the initial substrate 100′) dielectric layer pair; or performing a plurality of “trim-etch” cycles on a predetermined portion of the stacked structure 200′, such that the predetermined portion of the stacked structure 200′ has one or more sloped edges and a top (away from the initial substrate 100′) dielectric layer pair that is longer than the bottom (closer to the initial substrate 100′) dielectric layer pair.

Any suitable etching process, such as at least one of a dry etching process and a wet etching process, may be used in the formation process of the initial stair unit structure 400′. In addition, for example, a plurality of chop processes may be used to form a plurality of wrapping-around initial stair steps 411′, and after the plurality of wrapping-around initial stair steps 411′ are formed, the predetermined portion of the stacked structure 200′ is formed as the initial stair unit structure 400′. In an example, the stacked structure 200′ may include a plurality of initial stair unit structures 400′, such as a first initial stair unit structure 410′ and a second initial stair unit structure 420′, and so on.

With reference to FIG. 16 to FIG. 18, as an example, forming the initial stair unit structure in the stacked structure may further include: forming a plurality of wrapping-around initial stair steps 411′; and removing a portion of the initial stair step 411′, so that the same initial stair step 411′ is formed as stair steps of a plurality of initial sub-regions adjacent to each other, such as a stair step 411′-1 of the initial first sub-region 401′, a stair step 411′-2 of the initial second sub-region 402′, a stair step 411′-3 of the initial third sub-region 403′, and a stair step 411′-4 of the initial fourth sub-region 404′, etc.

The stacked structure 200′ may include a first surface 2021′ and a second surface 2022′ opposite to each other in the z-direction. The distances between the stair steps of the plurality of initial sub-regions and one of the two surfaces in the z-direction are different. For example, a distance between a stair step 411′-1 of the initial first sub-region 401′ and the first surface 2021′ is H1, a distance between a stair step 411′-4 of the initial fourth sub-region 404′ and the first surface 2021′ is H2, and the distance H1 is different from the distance H2.

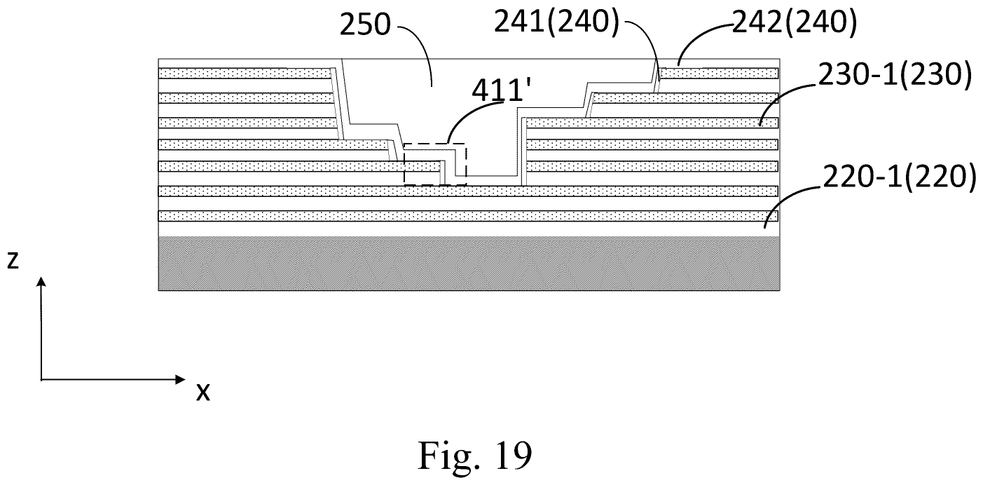

FIG. 19 is a schematic top view of a structure formed after the sacrificial layer 240 is formed according to an implementation of the present disclosure.

As shown in FIG. 18 to FIG. 19, in some implementations of the present disclosure, the method of manufacturing 2000 of the semiconductor device further includes: after the initial stair step 411′ is formed, forming a cover sacrificial layer 240 on a portion of the gate sacrificial layer 230 located on the surface of the initial stair step 411′.

In an example, the cover sacrificial layer 240 is formed on a portion of the gate sacrificial layer 230 located on the surface of the initial stair step 411′ by one or more thin film deposition processes, which may include, but are not limited to, Chemical Vapor Deposition (CVD), Physical Vapor Deposition (PVD), Atomic Layer Deposition (ALD), or any combination thereof.

The cover sacrificial layer 240 may be a composite structure. For example, the cover sacrificial layer 240 may include a first cover sacrificial layer 241 and a second cover sacrificial layer 242. The surface of the initial stair step 411′ may include a top surface 4111 and a side surface 4112, where the top surface 4111 may also be understood as a partial surface of the gate sacrificial layer 230. As an example, a first cover sacrificial layer 241 may be formed on a side surface 4112 of the initial stair step 411′, and a second cover sacrificial layer 242 may be formed on a surface of the initial stair step 411′ formed with the first cover sacrificial layer 241.

For example, the first cover sacrificial layer 241 may include, but is not limited to, an insulating dielectric material layer such as a silicon oxide layer. The second cover sacrificial layer 242 may include, but is not limited to, a modified silicon nitride material layer, a modified polysilicon material layer, or the like, where the polysilicon material layer may or may not be doped. As an example, a denaturation treatment may be performed on the surface of the second sacrificial layer 242, which may include ion implantation or plasma implantation processes, etc.

### Operation S3

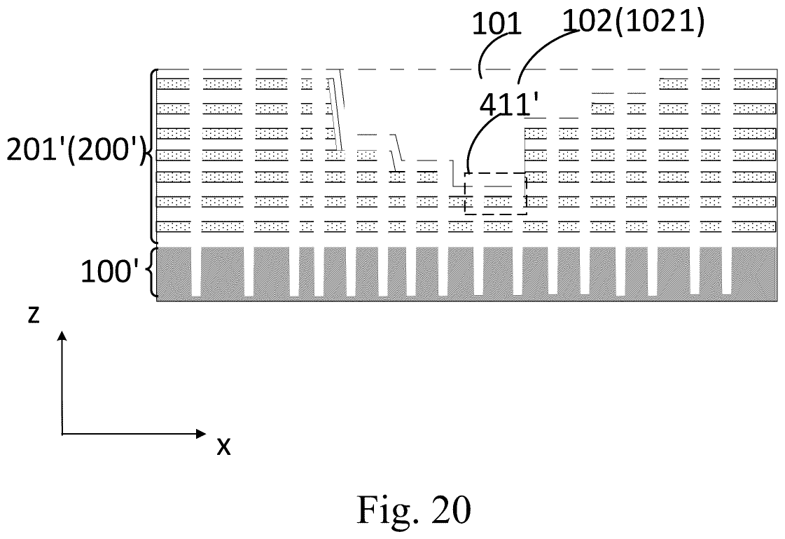

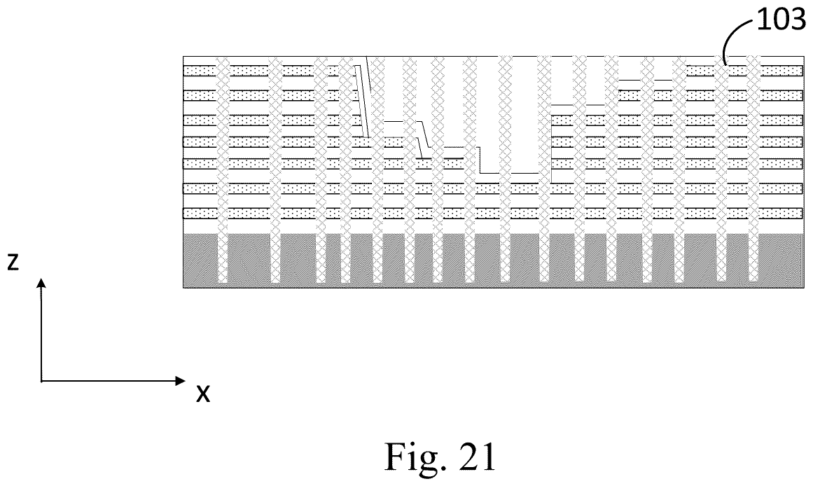

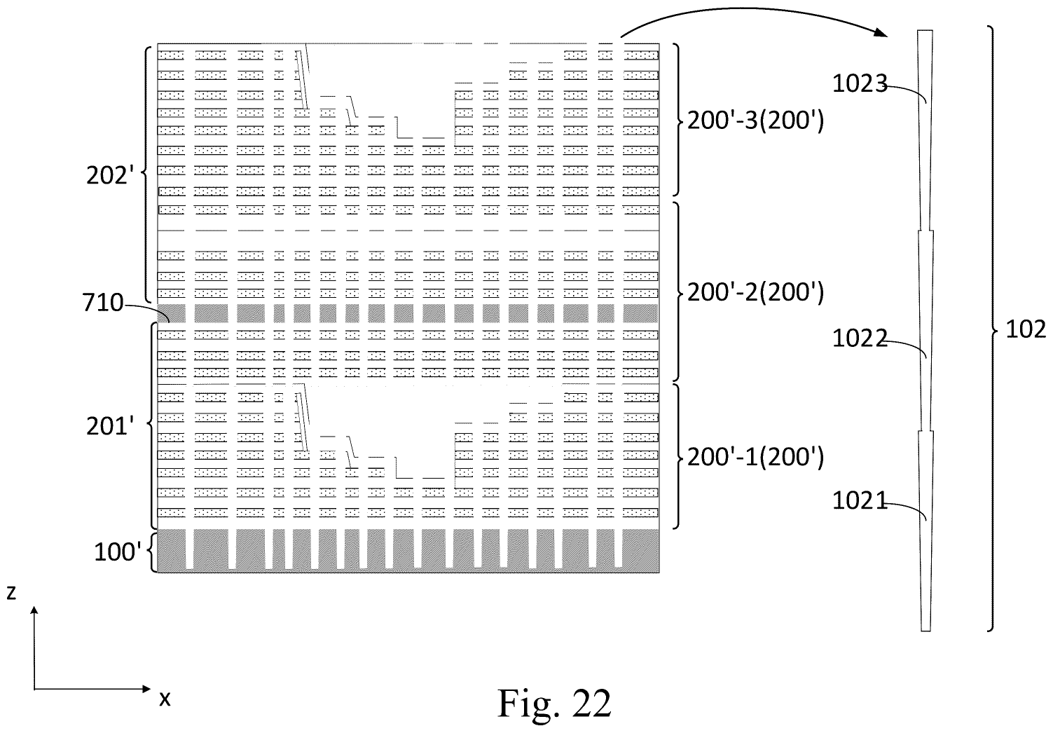

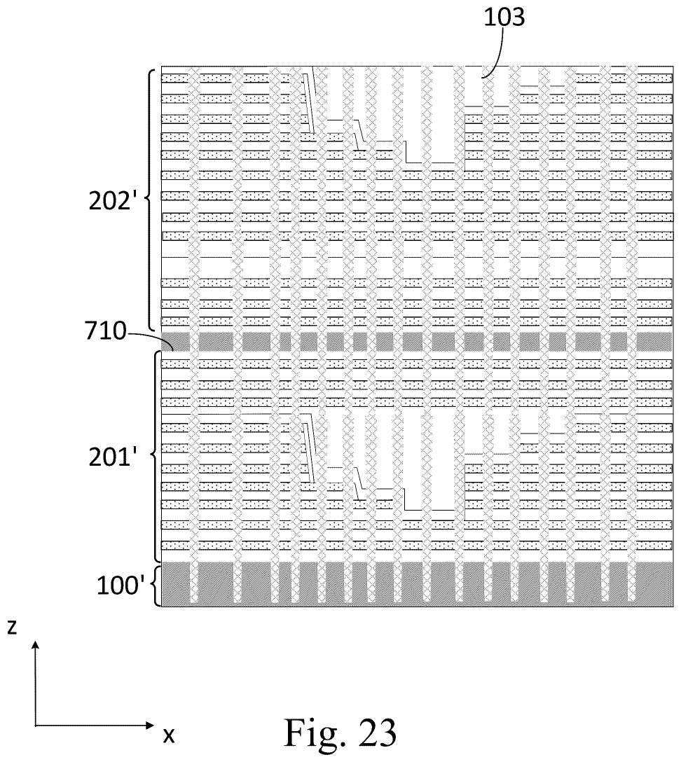

FIG. 20 is a schematic cross-sectional view of a structure formed after a channel hole 101 and a contact hole 102 are formed according to an implementation of the present disclosure. FIG. 21 is a schematic cross-sectional view of a structure formed after a filling sacrificial layer 103 is formed according to an implementation of the present disclosure. FIG. 22 is a schematic cross-sectional view of a structure formed after a channel hole 101 and a contact hole 102 are formed according to another implementation of the present disclosure. FIG. 23 is a schematic cross-sectional view of a structure formed after a filling sacrificial layer 103 is formed according to another implementation of the present disclosure.

As shown in FIGS. 19-23, in some implementations of the present disclosure, the operation S3 of forming a contact hole penetrating through the initial stair step along the first direction and connected with a gate sacrificial layer may for example include: removing a portion of the initial stacked structure 200′, thereby forming the contact hole 102, for example, by a dry etching process or a combination of a dry etching process and a wet etching process; or by performing other manufacturing processes, for example, a patterning process including photolithography, cleaning, and chemical mechanical polishing, etc. As an example, the contact hole 102 may penetrate through the initial stair step 411′ along the z-direction and extend into the initial substrate 100′.

In addition, in order to simplify the manufacturing process of the semiconductor device and reduce the manufacturing cost of the semiconductor device, the channel hole 101 may be formed in the process of forming the contact hole 102, and the channel hole 101 may be used to subsequently form the channel structure. In an example, both the channel hole 101 and the contact hole 102 may penetrate through the initial stair step 411′ along the z-direction and extend into the initial substrate 100′.

In addition, FIGS. 19-21 illustrate a process of forming contact holes 102 in a stacked structure 200′ formed in a single-stacking manner; and FIGS. 22-23 illustrate a process of forming contact holes 102 in a stacked structure 200′ formed in a double-stacking manner.

In an example, as shown in FIG. 22, the contact hole 102 in the stacked structure 200′ formed in the double-stacking manner may include a first hole 1021, a second hole 1022, and a third hole 1023 which may communicate with each other. In addition, the first sub-stacked structure 201′ and the second sub-stacked structure 202′ included in the stacked structure 200′ formed in the double-stacking manner may be formed by three single-stacking structures, such as the first stacked portion 200′-1, the second stacked portion 200′-2, and the third stacked portion 200′-3. In this way, the number of layers of the finally formed stacked structure 200 may be increased.

As shown in FIG. 19, after the initial stair step 411′ is formed, a cover step dielectric layer 250 covering the initial stair step 411′ may be formed by one or more thin film deposition processes, which may include, but are not limited to, Chemical Vapor Deposition (CVD), Physical Vapor Deposition (PVD), Atomic Layer Deposition (ALD), or any combination thereof. For example, the cover step dielectric layer 250 may include, but is not limited to, an insulating dielectric material layer such as a silicon oxide layer.

In an example, a planarization process may also be performed on the cover step dielectric layer 250, so that the cover step dielectric layer 250 has a flat surface, so as to facilitate subsequently forming a first hole 1021 (as shown in FIG. 20) of the contact hole 102 (as shown in FIG. 20) via the surface, and the planarization process may include a chemical mechanical polishing process.

As shown in FIGS. 20 and 21, after the first hole 1021 of the contact hole 102 is formed, a filling sacrificial layer 103 may be formed in the first hole 1021 by a thin film deposition process such as Chemical Vapor Deposition (CVD), Physical Vapor Deposition (PVD), Atomic Layer Deposition (ALD), or any combination thereof. The filling sacrificial layer 103 may include a carbon-containing material layer. The filling sacrificial layer 103 may be formed of a material having a high deposition rate to facilitate rapid filling of the first hole, and the filling sacrificial layer 103 should be any material with a high dry etching selectivity with respect to the first insulating dielectric layer 220-1 (as shown in FIG. 19) and the first gate sacrificial layer 230-1 (as shown in FIG. 19) to be removed easily in the subsequent operations.

In addition, in implementations where the contact hole 102 and the channel hole 101 are formed in the same process, the filling sacrificial layer 103 may be formed in the contact hole 102 and the channel hole 101.

As shown in FIG. 21 and FIG. 22, after the filling sacrificial layer 103 is formed, the second stacked portion 200′-2 may be formed by the method described in the operation S1, which will not be repeated here. In addition, after the second stacked portion 200′-2 is formed, a similar process as that of forming the first hole 1021 may also be used to form a second hole 1022 extending in the second stacked portion 200′-2 along the z-direction and communicating with the first hole 1021. In addition, a third stacked portion 200′-3, and a third hole 1023 extending in the third stacked portion 200′-3 along the z-direction and communicating with the second hole 1022 may be further formed by repeating the above operations.

Due to the limitations of the etching process, each of the first hole 1021, the second hole 1022, and the third hole 1023 described above extends along the z-direction, and the size of the bottom of each hole tends to decrease as the depth of the hole increases, so the size of the top of each hole is larger than the size of the bottom of the hole in a direction (for example, the x-direction) intersecting with the z-direction.

It should be noted that, in order to make the first sub-stacked structure 201′ and the second sub-stacked structure 202′ to be connected together in parallel, the first semiconductor layer 710 may be formed in the second stacked portion 200′-2. In addition, the first semiconductor layer 710 may be formed by the method described in the operation S1, which will not be repeated here.

As shown in FIGS. 22 and 23, after the contact hole 102 is formed, a filling sacrificial layer 103 may be formed in the contact hole 102. In addition, in implementations where the contact hole 102 and the channel hole 101 are formed in the same one process, the filling sacrificial layer 103 may be formed in the contact hole 102 and the channel hole 101.

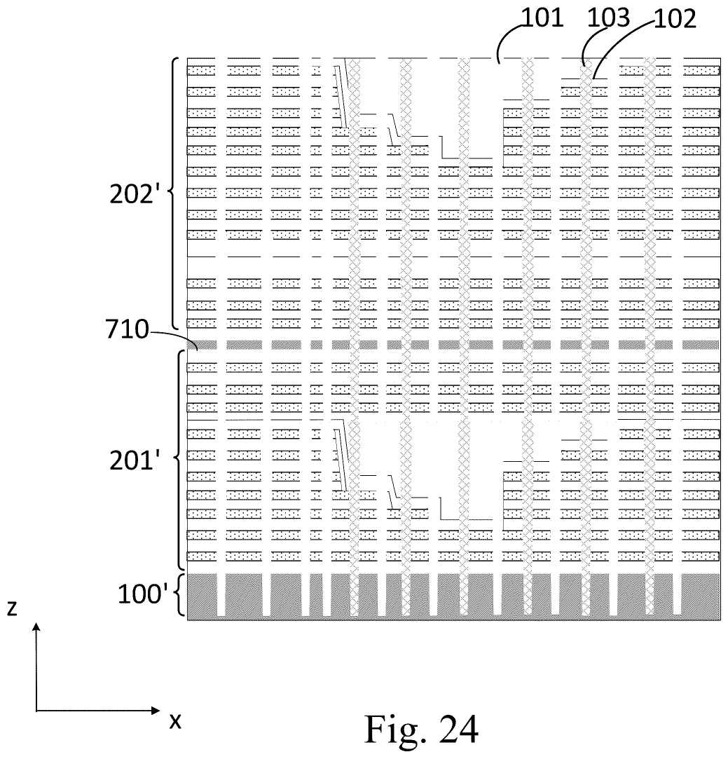

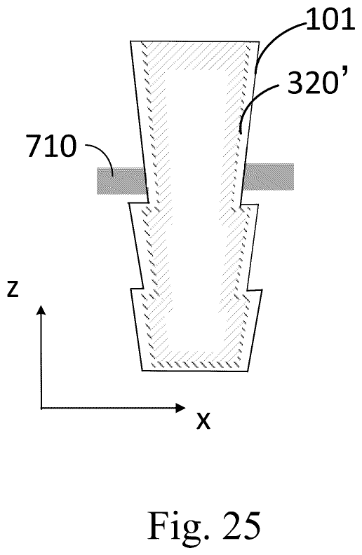

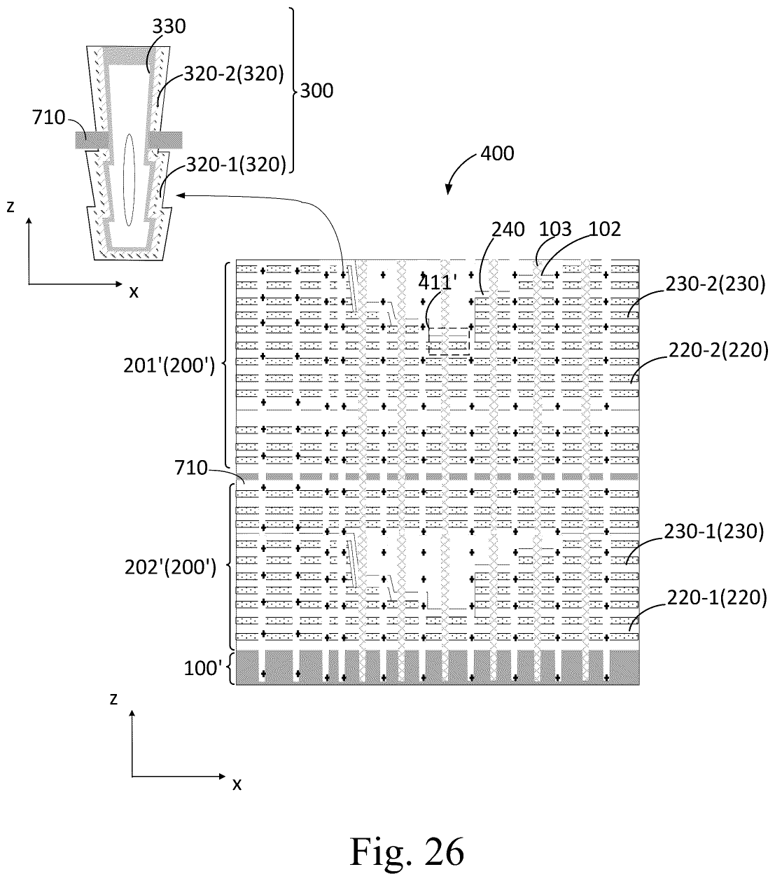

FIG. 24 is a schematic cross-sectional view of a structure formed after the channel hole 101 is exposed according to another implementation of the present disclosure. FIG. 25 is a schematic partial cross-sectional view of a structure formed after an initial functional layer 320′ is formed according to another implementation of the present disclosure. FIG. 26 is a schematic cross-sectional view of a structure formed after a channel structure 300 is formed according to another implementation of the present disclosure.

As shown in FIGS. 23-26, in some implementations of the present disclosure, the method of manufacturing 2000 of the semiconductor device further includes forming a channel structure 300, and forming the channel structure 300 may include, for example, forming a channel hole 101 extending in the first sub-stacked structure 201′ and the second sub-stacked structure 202′ along the z-direction, where the channel hole 101 exposes a portion of the first semiconductor layer 710; forming an initial functional layer 320′ in the channel hole 101; removing a portion of the initial functional layer 320′ located on the exposed portion of the first semiconductor layer 710 to form a first functional layer 320-1 and a second functional layer 320-2, where the first functional layer 320-1 extends in the first sub-stacked structure 201′ along the z-direction, and the second functional layer 320-2 extends in the second sub-stacked structure 202′ along the z-direction; and forming a channel layer 330 on the surfaces of the first functional layer 320-1, the first semiconductor layer 710, and the second functional layer 320-2.

In an example, as shown in FIGS. 23-24, a portion of the filling sacrificial layer 103 located in the channel hole 101 may be removed so as to expose the channel hole 101 by, for example, a dry etching process or a combination of a dry etching process and a wet etching process or by performing other manufacturing processes, for example, a patterning process including photolithography, cleaning, and chemical mechanical polishing, etc. Further, the channel hole 101 may expose a portion of the first semiconductor layer 710.

As an example, the channel hole 101 penetrates through the second sub-stacked structure 202′, the first semiconductor layer 710, and the first sub-stacked structure 201′ along the z-direction, and extends into the substrate 100′.

In an example, the plurality of channel holes 101 may have the same depth in the z-direction to reduce the difficulty of manufacturing the semiconductor device and reduce the cost of manufacturing the semiconductor device. In an example, the plurality of channel holes 101 and the plurality of contact holes 102 may have the same depth in the z-direction, thereby enhancing the above effects.

As shown in FIGS. 24-25, an initial functional layer 320′ may be formed on an inner wall of the channel hole 101 by a thin film deposition process such as Chemical Vapor Deposition (CVD), Physical Vapor Deposition (PVD), Atomic Layer Deposition (ALD), or any combination thereof.

The initial functional layer 320′ may include a blocking layer formed on an inner wall of the channel hole 101 and on the exposed portion of the first semiconductor layer 710 to block charge flow-out; a charge trapping layer formed on a surface of the blocking layer to store charge during an operation of the semiconductor device; and a tunneling layer formed on a surface of the charge trapping layer.

In some implementations of the present disclosure, the initial functional layer 320′ may include an ONO structure. However, in some other implementations, the initial functional layer 320′ may have a structure different from the ONO configuration.

In addition, those skilled in the art should understand that, without departing from the teachings of the present disclosure, depending on different architectures of the semiconductor device, an initial functional layer may be formed on the sidewall and the bottom surface of the channel hole, or an initial functional layer may be formed on the sidewall of the channel hole, which is not limited in the present disclosure.

As shown in FIGS. 25-26, a portion of the initial functional layer 320′ located on the exposed portion of the first semiconductor layer 710 may be removed by, for example, a dry etching process or a combination of a dry etching process and a wet etching process, or by performing other manufacturing processes, for example, a patterning process including photolithography, cleaning, and chemical mechanical polishing, and the like, to form the first functional layer 320-1 and the second functional layer 320-2, where the first functional layer 320-1 extends in the first sub-stacked structure 201′ along the z-direction, and the second functional layer 320-2 extends in the second sub-stacked structure 202′ along the z-direction.

In an example, after the portion of the initial functional layer 320′ located on the exposed portion of the first semiconductor layer 710 is removed, and the portion of the first semiconductor layer 710 is re-exposed, a new semiconductor material layer may be formed on the surface of the re-exposed portion of the first semiconductor layer 710 by a thin film deposition process such as Chemical Vapor Deposition (CVD), Physical Vapor Deposition (PVD), Atomic Layer Deposition (ALD), or any combination thereof, to reduce damage to the first semiconductor layer 710 by the process of “removing a portion of the initial functional layer 320′ located on the exposed portion of the first semiconductor layer 710”.

After the first functional layer 320-1 and the second functional layer 320-2 are formed, a channel layer 330 may be formed on surfaces of the first functional layer 320-1, the first semiconductor layer 710, and the second functional layer 320-2 by a thin film deposition process such as Chemical Vapor Deposition (CVD), Physical Vapor Deposition (PVD), Atomic Layer Deposition (ALD), or any combination thereof. In other words, the surface of the channel layer 330 is in direct contact with the surface of the first semiconductor layer 710, thereby making them be connected.

In an example, the channel layer 330 may be used to transport the desired charge (electrons or holes). The channel layer 330 may be made of a semiconductor material such as polysilicon or monocrystalline silicon, and may have a conductive impurity. For example, the channel layer 330 may be an N-type doped or a P-type doped polysilicon layer. Like the channel hole 101, the channel layer 330 may also have a cylindrical or cylindrical shape extending along the z-direction. As an example, the channel layer 330 may also extend into the substrate 100′.

In addition, as shown in FIG. 26, the channel structure 300 further includes a channel plug formed at an end (which may be understood as a top end of the channel structure 300) of the channel hole 101 (as shown in FIG. 24) away from the substrate 100′. In an example, after the channel layer 330 is formed, the channel hole 101 may be filled with a channel filling dielectric layer. The channel filling dielectric layer may include an oxide dielectric layer, such as silicon oxide or the like. In addition, during the filling process, a plurality of insulating gaps may be formed in the channel filling dielectric layer by controlling the channel filling process to reduce a structural stress. A channel plug is then formed in a portion of the channel filling dielectric layer located at the top of the channel hole 101. The channel plug may be made of the same material as the channel layer 330, such as N-type doped or P-type doped polysilicon. The channel plug is connected with the channel layer 330.

Further, as an example, based on the channel structure 300 that penetrates through the initial stair step 411′ not having the storage function, the channel hole 101 may be filled with only the insulating dielectric material layer such as a silicon oxide layer by a thin film deposition process such as Chemical Vapor Deposition (CVD), Physical Vapor Deposition (PVD), Atomic Layer Deposition (ALD), or any combination thereof. Similarly, a plurality of insulating gaps may also be formed in the insulating dielectric material layer by controlling the channel filling process to reduce the structural stress of the channel structure 300.

In addition, operation S3 of forming a contact hole penetrating through the initial stair step along the first direction and connected with the gate sacrificial layer may further include: removing a portion of the cover sacrificial layer 240 via the contact hole 102, so as to expand a radial size of a portion of the contact hole 102 in a direction intersecting with the z-direction. In order to simplify the manufacturing process of the semiconductor device and reduce the manufacturing cost of the semiconductor device, the step of “removing a portion of the cover sacrificial layer 240 via the contact hole 102” may be performed after the gate layer is formed in the operation S4.

### Operation S4

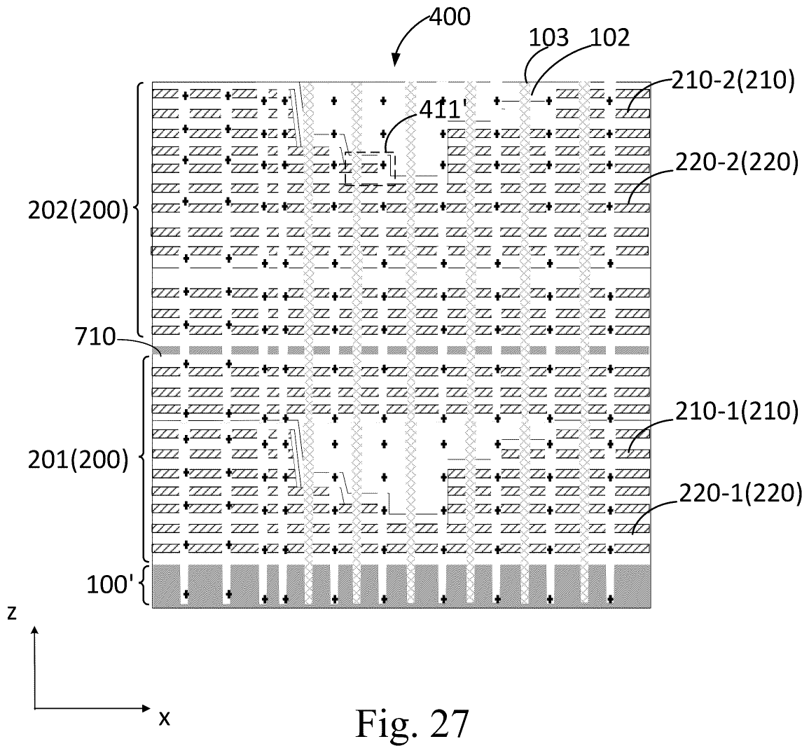

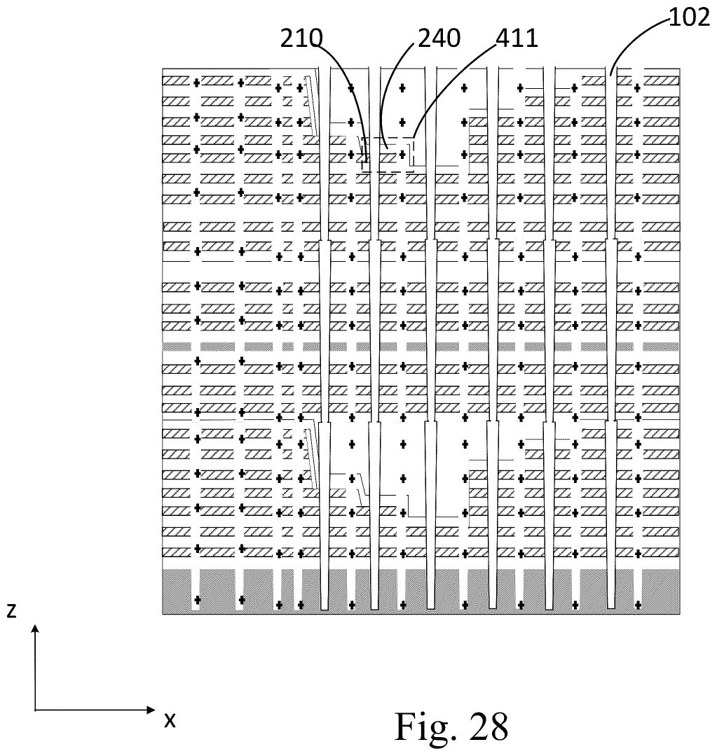

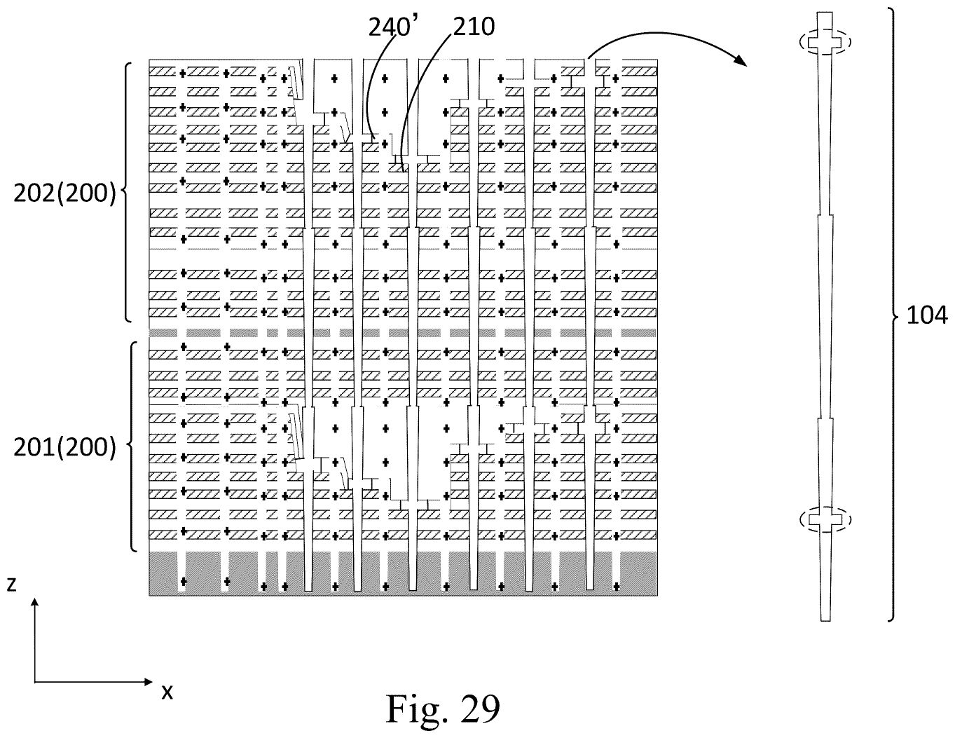

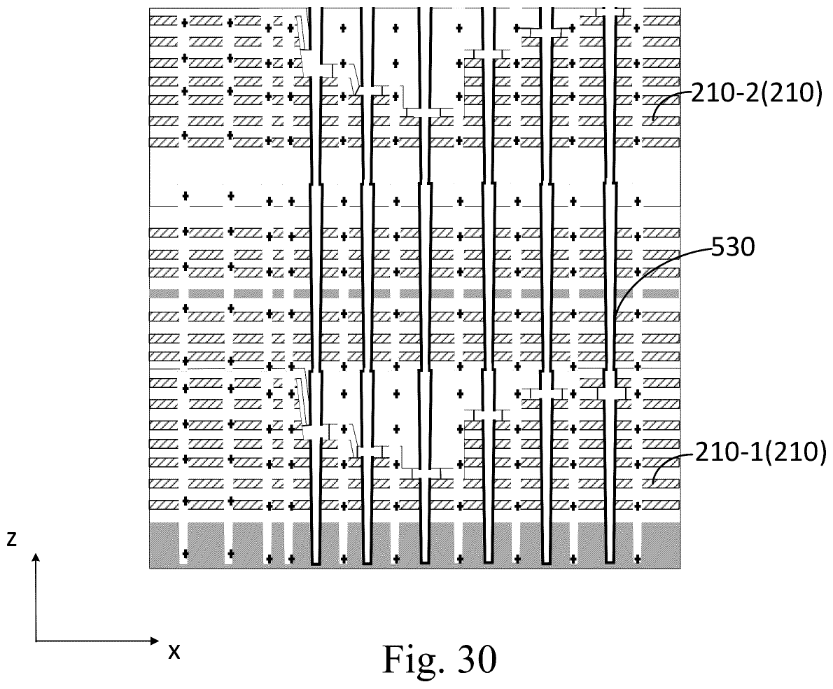

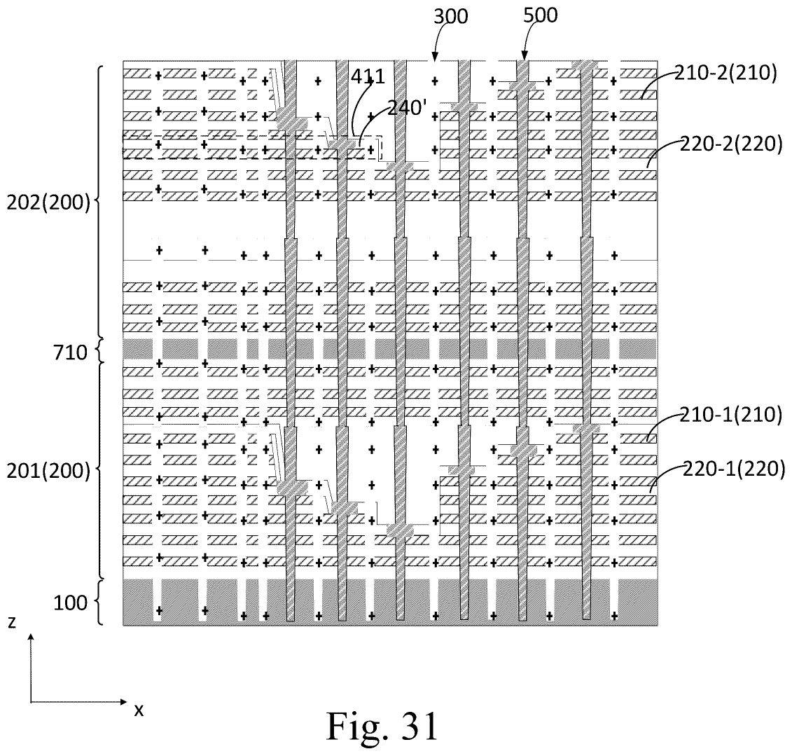

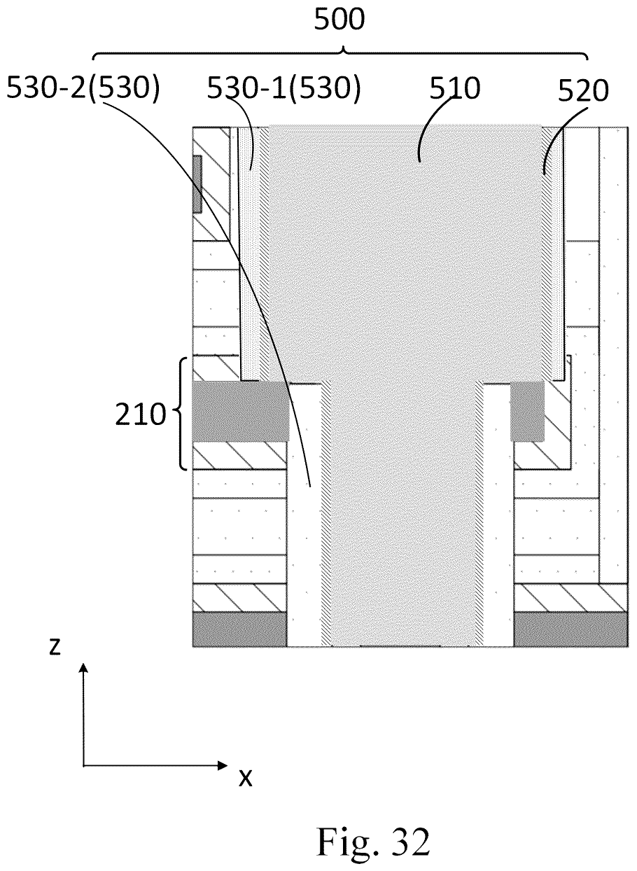

FIG. 27 is a schematic cross-sectional view of a structure formed after the gate layer 210 is formed according to another implementation of the present disclosure. FIG. 28 is a schematic cross-sectional view of a structure formed after the contact hole 102 is exposed according to another implementation of the present disclosure. FIG. 29 is a schematic cross-sectional view of a structure formed after a portion of the cover sacrificial layer 240 is removed according to another implementation of the present disclosure. FIG. 30 is a schematic cross-sectional view of a structure formed after the blocking layer 530 is formed according to another implementation of the present disclosure. FIG. 31 is a schematic cross-sectional view of a structure formed after the contact structure 500 is formed according to another implementation of the present disclosure. FIG. 32 is a schematic cross-sectional view of a structure formed after the contact structure 500 is formed according to another implementation of the present disclosure.

As shown in FIGS. 26-32, in some implementations of the present disclosure, operation S4 of removing the gate sacrificial layer and forming the contact structure in the contact hole may include, for example, removing the gate sacrificial layer 230 and forming the gate layer 210; exposing the contact hole 102; and forming the contact structure 500.

Referring to FIG. 5, FIG. 9 and FIG. 10, in some implementations of the present disclosure, the finally formed semiconductor device may include a gate line isolation structure 900, which may extend along a y-direction intersecting with both the x-direction and the z-direction.

As shown in FIGS. 26-27, a gate line slit (not shown) generated in the process of forming the gate line isolation structure 900 (as shown in FIG. 10) may serve as a path for providing an etchant, so that the gate sacrificial layer 230 may be removed by a process such as a wet etching. In a gap (not shown) formed after the gate sacrificial layer 230 is removed, a gate layer 210 may be formed.

In an example, the gate line slit may be formed by, for example, a dry etching process or a combination of a dry etching process and a wet etching process, or by performing other manufacturing processes, such as a patterning process including photolithography, cleaning, and chemical mechanical polishing. The gate line slit may extend along the y-direction in the stacked structure 200′. In addition, the gate line slit may also penetrate through the second sub-stacked structure 202′, the first semiconductor layer 710, and the first sub-stacked structure 201′ along the z-direction, and extend into the initial substrate 100′.

In an example, the gate sacrificial layer 230 may be removed by a process such as a wet etching. By the gate line slit, the etchant and the chemical precursor are brought into contact with the gate sacrificial layer 230, and then the gate sacrificial layer 230 is removed to form a gap.

After the gap is formed, the gate layer 210 may be formed in the gap by a thin film deposition process such as Chemical Vapor Deposition (CVD), Physical Vapor Deposition (PVD), Atomic Layer Deposition (ALD), or any combination thereof. The gate layer 210 may include a first gate layer 210-1 and a second gate layer 210-2. The first gate layer 210-1 may be formed in a space formed by removing the first gate sacrificial layer 230-1; and the second gate layer 210-2 may be formed in a space formed by removing the second gate sacrificial layer 230-2. After the gate layer 210 is formed, the stacked structure 200′ is formed as a stacked structure 200. In addition, the initial stair step 411′ is formed as a stair step 411, and the initial stair unit structure 400′ is formed as a stair unit structure 400.

The first gate layer 210-1 and the second gate layer 210-2 may each include a conductive material, which may include any one or a combination of a conductive metal material and a doped semiconductor material, where the conductive metal material may be, for example, tungsten (W), cobalt (Co), copper (Cu), aluminum (Al), or the like, and the doped semiconductor material may be, for example, doped crystalline silicon or silicide, which is not limited in the present disclosure.

In addition, in some implementations of the present disclosure, after the first gate layer 210-1 and the second gate layer 210-2 are formed, the gate line isolation structure 900 (as shown in FIG. 10) may be further formed by filling the gate line slit. In an example, a thin film deposition process such as Chemical Vapor Deposition (CVD), Physical Vapor Deposition (PVD), Atomic Layer Deposition (ALD), or any combination thereof may be used to form a gate line isolation layer and a gate line filling layer on a surface of the gate line isolation layer in the gate line slit.

In an example, a material of the gate line isolation layer may include at least one of a high dielectric constant dielectric layer and an insulating dielectric material layer such as a silicon oxide layer. In addition, the material of the gate line filling layer may include at least one of a semiconductor material such as polysilicon, and an insulating dielectric material layer such as silicon oxide, silicon nitride, and silicon oxynitride. In an example, the material of the gate line filling layer may further include a conductive material layer. The inner filling material of the gate line isolation structure 900 is not limited in the present disclosure.

As shown in FIG. 28 to FIG. 29, after the gate layer 210 is formed, the method of manufacturing 2000 of the semiconductor device further includes: removing a portion of the cover sacrificial layer 240 via the contact hole 102, so that the subsequently formed contact structure 500 (as shown in FIG. 31) is connected with a portion of the surface of the gate layer 210 exposed after the sacrificial layer 240 is removed.

As shown in FIGS. 27-28, a portion of the filling sacrificial layer 103 located in the contact hole 102 may be removed by, for example, a dry etching process or a combination of a dry etching process and a wet etching process, or by performing other manufacturing processes, such as a patterning process including photolithography, cleaning, and chemical mechanical polishing, so as to expose the contact hole 102. As shown in FIG. 28, a portion of the gate layer 210 located on the surface of the stair step 411 is covered with a cover sacrificial layer 240.

As shown in FIGS. 28-29, a portion of the cover sacrificial layer 240 may be removed via the contact hole 102 by, for example, a dry etching process or a combination of a dry etching process and a wet etching process, or by performing other manufacturing processes, such as a patterning process including photolithography, cleaning, and chemical mechanical polishing, thereby expanding the radial size of a portion of contact hole 102 in a direction (e.g., x-direction) intersecting with the z-direction, and forming an outward expanding contact hole 104. In addition, after the portion of the cover sacrificial layer 240 is removed, a portion of the surface of the gate layer 210 is exposed in the outward expanding contact hole 104, and may be connected with a subsequently formed contact structure 500 (as shown in FIG. 31). The remaining portions of the cover sacrificial layer 240 are formed as a cover dielectric layer 240′.

As shown in FIG. 29 to FIG. 32, forming the contact structure 500 may, for example, include: forming a blocking layer 530 on the outward expanding contact hole 104; and sequentially forming an adhesive layer 520 and a conductive core layer 510 on the surface of the blocking layer 530 and the surface of the gate layer 210.

In an example, referring to FIGS. 29-30 and 32, a blocking layer 530 may be formed in the outward expanding contact hole 104 by a thin film deposition process such as Chemical Vapor Deposition (CVD), Physical Vapor Deposition (PVD), Atomic Layer Deposition (ALD), or any combination thereof. The blocking layer 530 may include any suitable dielectric material, such as silicon oxide, silicon nitride, silicon oxynitride, or a high-k dielectric. The blocking layer 530 includes a first sub-layer 530-1 and a second sub-layer 530-2 that are spaced apart from each other in a direction (e.g., x-direction) intersecting with the z-direction. In an example, the first sub-layer 530-1 and the second sub-layer 530-2 of the blocking layer 530 may include different insulating dielectric materials.

Referring to FIGS. 30-32, after the blocking layer 530 is formed, a thin film deposition process such as Chemical Vapor Deposition (CVD), Physical Vapor Deposition (PVD), Atomic Layer Deposition (ALD), or any combination thereof may be used to sequentially form an adhesive layer 520 and a conductive core layer 510 on a surface of the blocking layer 530 and a surface of the gate layer 210, where the adhesive layer 520 and the conductive core layer 510 are both connected with the gate layer 210.

The adhesive layer 520 may include, but is not limited to, titanium, titanium nitride, tantalum, tantalum nitride, or the like. The adhesive layer is used to block the diffusion of ions in the conductive core layer and improve the adhesive force between the conductive core layer and the blocking layer. The conductive core layer 510 may include any one or a combination of a conductive metal material and a doped semiconductor material, where the conductive metal material may be, for example, tungsten (W), cobalt (Co), copper (Cu), aluminum (Al), or the like, and the doped semiconductor material may be, for example, doped crystalline silicon or silicide, which is not limited in the present disclosure.

It should be noted that FIG. 32 and FIG. 11 show internal structures of the contact structure 500 and the gate layer 210, and for ease of observation, the contact structure 500 and the gate layer 210 shown in FIG. 32 and FIG. 11 adopt different patterns from the contact structure 500 and the gate layer 210 shown in the rest of figures.

Therefore, according to the method of manufacturing the semiconductor device provided by at least one implementation of the present disclosure, the stair unit structure of the semiconductor device is located in the stacked structure and includes a plurality of wrapping-around stair steps. By the wrapping-around stair steps, the area where the stair step is located can be reduced while the contact structure and the gate layer are effectively connected, thereby improving the storage density of the semiconductor device. In addition, the connection between the gate layers of different sub-stacked structures and the peripheral circuit is achieved through the same contact structure, the number of contact structures in the semiconductor device is reduced, the manufacturing process of the contact structure is simplified while the storage density of the semiconductor device is improved, and the manufacturing cost of the semiconductor device is reduced.

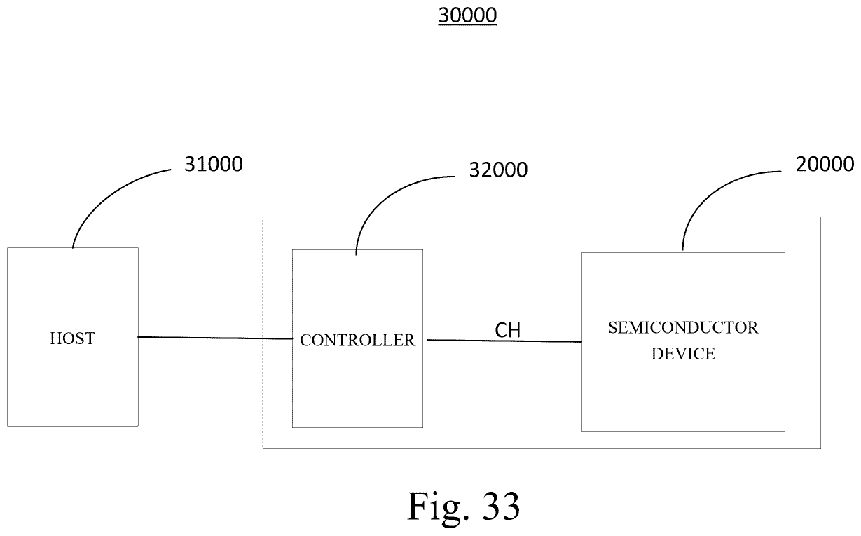

FIG. 33 is a schematic structural diagram of a memory system 30000 according to an implementation of the present disclosure.

As shown in FIG. 33, at least one implementation of yet another aspect of the present disclosure further provides a memory system 30000. The memory system 30000 may include a semiconductor device 20000 and a controller 32000. The semiconductor device 20000 may be the same as the semiconductor device described in any of the above implementations, and details thereof are not described herein again. The semiconductor device 20000 may be a two-dimensional semiconductor device or a three-dimensional semiconductor device, or even a part of a two-dimensional semiconductor device or a part of a three-dimensional semiconductor device. The following description will take the three-dimensional semiconductor device as an example for illustration.

As an example, the three-dimensional semiconductor device may include at least one of a three-dimensional NAND memory and a three-dimensional NOR memory.

The memory system 30000 may include a semiconductor device 20000 and a controller 32000. The semiconductor device 20000 may be the same as the semiconductor device described in any of the above implementations, and details thereof are not described herein again. The controller 32000 may control the semiconductor device 20000 through the channel CH, and the semiconductor device 20000 may perform operations based on the control of the controller 32000 in response to a request from the host 31000. The semiconductor device 20000 may receive the command (CMD) and the address (ADDR) from the controller 32000 through the channel CH and access an area selected from the array of memory cells in response to the address. In other words, the semiconductor device 20000 may perform an internal operation corresponding to the command on the area selected by the address.

In some implementations, the three-dimensional memory system may be implemented as a Universal Flash Storage (UFS) device, a Solid State Disk (SSD), a multimedia card in the form of an MMC, an eMMC, an RS-MMC, and a Micro-MMC, a Secure Digital Card in the form of a SD, a mini-SD and a Micro-SD, a storage device of Personal Computer Memory Card International Association (PCMCIA) card type, a storage device of Peripheral Component Interconnect (PCI) type, a storage device of PCI-Express (PCI-E) type, a compact flash (CF) card, a smart media card, or a memory stick, among others. The memory system provided by the present disclosure has the same beneficial effects as the semiconductor device, because the semiconductor device provided by the present disclosure is disposed therein, and thus the beneficial effects of the memory system provided by the present disclosure are not repeated herein again.

Although exemplary method of manufacturing and structure of a semiconductor device are described herein, it is understood that one or more features of the structure of the semiconductor device may be omitted or replaced, or one or more features may be added to the structure of the semiconductor device. Further, the listed materials of the various layers are merely exemplary.

The above description is only an example implementation of the present disclosure and illustration of the principles of the present disclosure. It should be understood by those skilled in the art that the protection scope of the present disclosure is not limited to the technical solutions formed by the selected combination of the above technical features, and should also cover other technical solutions formed by any combination of the foregoing technical features or their equivalent features without departing from the technical concept. For example, the technical solutions formed by replacing the above features with the technical features having similar functions disclosed in the present disclosure (but not limited thereto) would also fall within the protection scope of the present disclosure.

What is claimed is:

1. A semiconductor device, comprising:
a stacked structure comprising gate layers stacked along a first direction;
a stair unit structure located in the stacked structure and comprising a plurality of wrapping-around stair steps; and
a contact structure penetrating through the stair step along the first direction and connected with the gate layer.

2. The semiconductor device of claim 1, wherein:
the stacked structure comprises two surfaces opposite to each other in the first direction;
the stair unit structure comprises a plurality of stair unit structures; and
distances between the stair steps of the plurality of the stair unit structures and one of the two surfaces in the first direction are different.

3. The semiconductor device of claim 1, wherein in a direction intersecting with the first direction, a plurality of stair steps of a same stair unit structure have different sizes.

4. The semiconductor device of claim 1, wherein:
a shape of a cross section of the stair unit structure in a plane intersecting with the first direction comprises at least one of a circle, an ellipse, a polygon, and a sector;
a shape of a cross section of the stair step in a plane intersecting with the first direction comprises an annular shape; and
the annular shape comprises at least one of a circular ring, an elliptical ring, a polygonal ring, and a sector ring.

5. The semiconductor device of claim 1, wherein:
the stair unit structure comprises a plurality of stair unit structures; and
the plurality of stair unit structures have a different numbers of stair steps.

6. The semiconductor device of claim 1, wherein:
the stair unit structure comprises a plurality of sub-regions;
each sub-region of the plurality of sub-regions comprises a plurality of stair steps; and
the stacked structure comprises two surfaces opposite to each other in the first direction, and distances between the plurality of sub-regions and one of the two surfaces in the first direction are different.

7. The semiconductor device of claim 6, wherein distances between the stair steps of the plurality of sub-regions and one of the two surfaces in the first direction are different.

8. The semiconductor device of claim 1, wherein:
the stacked structure comprises a plurality of sub-stacked structures stacked along the first direction; and
the contact structure is connected to the gate layers of the plurality of sub-stacked structures.

9. The semiconductor device of claim 8, wherein a portion of the contact structure in the sub-stacked structure comprises:
a first contact portion extending to a surface of the gate layer along the first direction and connected with the surface; and
a second contact portion connected with the first contact portion and penetrating through the stair step in the first direction.

10. The semiconductor device of claim 9, wherein:
a portion of the first contact portion extending to the surface extends in a direction intersecting with the first direction;
the stair step comprises a cover dielectric layer covering the surface; and
a portion of the first contact portion extending to the surface is located in the cover dielectric layer.

11. The semiconductor device of claim 9, further comprising:
a peripheral circuit structure,
wherein the first contact portion or the second contact portion of the contact structure connects the gate layer with the peripheral circuit structure; and
wherein the peripheral circuit structure comprises:
a first peripheral circuit disposed on a first side of the stacked structure; and
a second peripheral circuit disposed on a second side of the stacked structure, wherein the first side and the second side are opposite to each other along the first direction;
wherein the first contact portion is closer to the first side than the second contact portion; and
wherein the first contact portion connects the gate layer with the first peripheral circuit, or the second contact portion connects the gate layer with the second peripheral circuit.

12. The semiconductor device of claim 1, wherein the contact structure comprises:
a conductive core layer;
an adhesive layer surrounding the conductive core layer; and
a blocking layer surrounding the adhesive layer and comprising first and second sub-layers spaced apart from each other in a direction intersecting with the first direction.

13. The semiconductor device of claim 1, wherein:
the stacked structure comprises a first sub-stacked structure and a second sub-stacked structure disposed on a side of the first sub-stacked structure along the first direction;
the contact structure comprises a first sub-portion, a second sub-portion, and a third sub-portion connected to each other along the first direction;
the first sub-portion and a portion of the second sub-portion are located in the first sub-stacked structure, and the other portion of the second sub-portion and the third sub-portion are located in the second sub-stacked structure; and
the semiconductor device further comprises:
a peripheral circuit structure disposed on a first side of the stacked structure along the first direction,
wherein the second sub-portion is closer to the peripheral circuit structure than the first sub-portion, a first end of the first sub-portion is connected with a second end of the second sub-portion, and in a direction intersecting with the first direction, a size of the first end is greater than a size of the second end; and
wherein the third sub-portion is closer to the peripheral circuit structure than the second sub-portion, a third end of the second sub-portion is connected with a fourth end of the third sub-portion, and in a direction intersecting with the first direction, a size of the third end is greater than a size of the fourth end.

14. The semiconductor device of claim 13, further comprising:
a peripheral circuit structure disposed on a first side of the stacked structure along the first direction,
wherein at least one of the first sub-portion, the second sub-portion, and the third sub-portion comprises an end and the other end opposite to each other along the first direction, and the end is closer to the peripheral circuit structure than the other end; and
wherein in a direction intersecting with the first direction, a size of the end is larger than a size of the other end.

15. The semiconductor device of claim 1, wherein:
the stacked structure comprises a first sub-stacked structure and a second sub-stacked structure disposed on a side of the first sub-stacked structure along the first direction; and
the semiconductor device further comprises a first semiconductor layer located between the first sub-stacked structure and the second sub-stacked structure along the first direction and extending along a direction intersecting with the first direction.

16. The semiconductor device of claim 1, wherein:
the stacked structure comprises a plurality of sub-stacked structures stacked along the first direction; and
the semiconductor device further comprises:
a second semiconductor layer located on a side of the sub-stacked structure along the first direction and extending along a direction intersecting with the first direction,
the second semiconductor layers of the plurality of sub-stacked structures are connected to each other.

17. A method of manufacturing a semiconductor device, comprising:
alternately stacking insulating dielectric layers and gate sacrificial layers along a first direction to form a stacked structure;
forming an initial stair unit structure in the stacked structure, wherein the initial stair unit structure comprises a plurality of wrapping-around initial stair steps;
forming a contact hole penetrating the initial stair step along the first direction and connected with the gate sacrificial layer; and
removing the gate sacrificial layer and forming a contact structure in the contact hole.

18. The method of claim 17, further comprising:
after the initial stair step is formed, forming a cover sacrificial layer on a portion of the gate sacrificial layer on a surface of the initial stair step; and
after removing the gate sacrificial layer to form a gate layer, removing a portion of the cover sacrificial layer via the contact hole,
wherein the contact structure is connected with a surface of the gate layer exposed after removing the portion of the cover sacrificial layer.

19. The method of claim 17, wherein forming the initial stair unit structure in the stacked structure comprises:
forming a plurality of wrapping-around initial stair steps; and
removing a portion of the initial stair step, so that the same initial stair step is formed as stair steps of a plurality of initial sub-regions adjacent to each other,
wherein the stacked structure comprises two surfaces opposite to each other in the first direction; and
wherein distances between the stair steps of the plurality of initial sub-regions and one of the two surfaces in the first direction are different.

20. A memory system, comprising:
at least one semiconductor device, comprising:
a stacked structure comprising gate layers stacked along a first direction;
a stair unit structure located in the stacked structure and comprising a plurality of wrapping-around stair steps; and
a contact structure penetrating through the stair step along the first direction and connected with the gate layer; and
a controller coupled to the semiconductor device and configured to control the semiconductor device to store data.
